(19) United States
(12) Patent Application Publication
(10) Pub. No.: US 2026/0367405 A1
(43) Pub. Date: Nov. 19, 2026

(54) PROJECTION DEVICE AND ELECTRONIC DEVICE COMPRISING SAME

(71) Applicant: LG INNOTEK CO., LTD., Seoul (KR)

(72) Inventors: Woo Young JUNG, Seoul (KR); Tae Wook KIM, Seoul (KR)

(21) Appl. No.: 19/476,074

(22) PCT Filed: Apr. 18, 2024
(86) PCT No.: PCT/KR2024/095755

§ 371 Date: Oct. 16, 2025

(30) Foreign Application Priority Data
Apr. 20, 2023 (KR) 10-2023-0052129
Apr. 20, 2023 (KR) 10-2023-0052130
Apr. 17, 2024 (KR) 10-2024-0051313
Apr. 17, 2024 (KR) 10-2024-0051314

(51) Int. Cl. G02B 27/01

(52) U.S. Cl. CPC G02B 27/0172; G02B 2027/0118; G02B 2027/013

(57) ABSTRACT

Disclosed in an embodiment is a projection device comprising: a plurality of light sources, which emit light and are spaced apart from each other; a first prism facing the plurality of light sources; an optical modulator for modulating the light; a reflecting unit arranged at the rear end of the first prism so as to reflect, to the optical modulator, the light that has passed through the first prism; a second prism arranged between the optical modulator and the reflecting unit; a projecting lens unit on which the light modulated in the optical modulator is incident; and a substrate having a top surface on which the first prism and the plurality of light sources are arranged.

### CROSS-REFERENCE TO RELATED APPLICATIONS

This application is the U.S. national stage application of International Patent Application No. PCT/KR2024/095755, filed Apr. 18, 2024, which claims the benefit under 35 U.S.C. § 119 of Korean Application Nos. 10-2023-0052129, filed Apr. 20, 2023; 10-2023-0052130, filed Apr. 20, 2023; 10-2024-0051313, filed Apr. 17, 2024; and 10-2024-0051314, filed Apr. 17, 2024; the disclosures of each of which are incorporated herein by reference in their entirety.

### TECHNICAL FIELD

Embodiments relate to a projection device and an electronic device including the same.

### BACKGROUND ART

Virtual reality (VR) refers to a specific environment, situation, or technology itself that resembles reality created by artificial technology using computers or the like but is not real. Augmented reality (AR) refers to a technology that combines virtual objects or information with a real environment to make it look like objects existing in the original environment.

Mixed reality (MR) or hybrid reality refers to the merging of the virtual worlds and real worlds to create new environments or new information. In particular, it is called mixed reality when it is possible to interact in real time between what exists in reality and what exists in the virtual in real time.

At this time, the created virtual environment, situation, or the like stimulates the user's five senses and enables spatial and temporal experiences similar to those of the real world, thereby enabling users to travel freely across the boundaries between reality and imagination. In addition, users can not only immerse themselves in such environments but also interact with the elements realized in such environments, such as adding operations and providing instructions using devices existing in the real space.

Recently, research on equipment (including gears and devices) used in these technical fields has been actively conducted. However, the need for miniaturization and improvement of optical performance of the equipment is emerging.

### DISCLOSURE

### Technical Problem

Embodiments provide a projection device and an electronic device in which manufacturability is improved through a substrate when using a projection device and an electronic device including the same that are used for augmented reality (AR) and the like.

In addition, embodiments may provide a projection device and an electronic device including the same in which optical alignment errors are eliminated by not using a bent or curved substrate by attaching a first prism and a light source to one surface of a substrate.

In addition, embodiments may provide a projection device and an electronic device including the same that are easy to miniaturize and have improved brightness and light collection through a collimating member.

In addition, embodiments may provide a projection device and an electronic device including the same in which color mixing is improved through a collimating member such as a Fresnel lens, and a first prism.

In addition, embodiments may provide a projection device and an electronic device including the same in which optical efficiency is improved by adjusting the position of a light source, a collimating member, or the like.

Objectives to be solved by the embodiment are not limited to the above-described objectives and will include objectives and effectiveness which may be identified by solutions for the objectives and the embodiments described below.

### Technical Solution

A projection device according to an embodiment includes a plurality of light sources configured to emit light and spaced apart from each other, a first prism facing the plurality of light sources, a light modulator configured to modulate the light, a reflection unit disposed at a rear end of the first prism and configured to reflect the light transmitted through the first prism toward the light modulator, a second prism disposed between the light modulator and the reflection unit, a projection lens unit on which the light modulated by the light modulator is incident, and a substrate including an upper surface on which the first prism and the plurality of light sources are disposed.

The substrate may include an exposed pad portion, and the pad portion may include a first pad and a second pad spaced apart from each other.

Each of the plurality of light sources may be electrically connected to the first pad and the second pad.

The projection device may further include a first conductive member and a second conductive member respectively disposed on the first pad and the second pad.

The projection device may further include a spacer disposed between the first conductive member and the second conductive member.

Each of the light sources may be in contact with the spacer.

The projection device may further include an adhesive member disposed between the first prism and the upper surface of the substrate.

A height of the adhesive member may be different from a height of the first conductive member or the second conductive member.

A height of the adhesive member may be greater than a height of the first conductive member or the second conductive member.

The substrate may include an alignment mark formed on the upper surface thereof.

An upper surface of the first prism may be disposed above an upper surface of each of the plurality of light sources.

The plurality of light sources may be disposed at the same height from the upper surface of the substrate.

In the plurality of light sources, a surface perpendicular to an emission surface of the light may face the upper surface of the substrate.

A projection device according to an embodiment includes a plurality of light sources configured to emit light and spaced apart from each other, a first prism facing the plurality of light sources, a light modulator configured to modulate the light, a reflection unit disposed at a rear end of the first prism and configured to reflect the light transmitted through the first prism toward the light modulator, a second prism disposed between the light modulator and the reflection unit, a projection lens unit on which the light modulated by the light modulator is incident, and a collimating member disposed at a front end or a rear end of the first prism.

The collimating member may include a first collimating member disposed between the first prism and the plurality of light sources.

The first collimating member may be in contact with the first prism.

The first collimating member may be disposed spaced apart from the first prism.

A first separation distance between the first collimating member and the first prism may be smaller than a second separation distance between the first collimating member and the plurality of light sources.

The first collimating member may include at least one of a Fresnel lens, a total internal reflection (TIR) Fresnel lens, a micro lens array (MLA), and a meta lens.

The first collimating member may reduce a radiation angle of light incident on the first prism.

An area of the first collimating member may be greater than an area of an outer side surface of the first prism facing the first collimating member.

The plurality of light sources may include a first light source, a second light source, and a third light source, which are spaced apart from each other and emit light of different wavelengths, and the first prism may include a first outer side surface facing the first light source, a second outer side surface facing the second light source, a third outer side surface facing the third light source, and a fourth outer side surface facing the reflection unit.

A plurality of first collimating members may be provided, and the plurality of first collimating members may respectively face the first outer side surface, the second outer side surface, and the third outer side surface.

The collimating member may include a second collimating member disposed between the first prism and the reflection unit.

The second collimating member may include a collimating lens.

The plurality of light sources may include a first light source, a second light source, and a third light source, which are spaced apart from each other and emit light of different wavelengths, and the first prism may include a first outer side surface facing the first light source, a second outer side surface facing the second light source, a third outer side surface facing the third light source, and a fourth outer side surface corresponding to the reflection unit.

The second collimating member may face the fourth outer side surface.

### Advantageous Effects

Embodiments can implement a projection device and an electronic device in which manufacturability is improved through a substrate, when using a projection device and an electronic device including the same that are used for augmented reality (AR) and the like.

In addition, embodiments can implement a projection device and an electronic device including the same in which optical alignment errors are eliminated by not using a bent or curved substrate by attaching a first prism and a light source to one surface of a substrate.

In addition, embodiments can implement a projection device and an electronic device including the same that are easy to miniaturize and have improved brightness and light collection through a collimating member.

In addition, embodiments can implement a projection device and an electronic device including the same in which color mixing is improved through a collimating member such as a Fresnel lens, and a first prism.

In addition, embodiments can implement a projection device and an electronic device including the same in which optical efficiency is improved by adjusting the position of a light source, a collimating member, or the like.

Various advantages and effects of the present invention are not limited to the above description and can be more easily understood through the description of specific exemplary embodiments of the present invention.

### DESCRIPTION OF DRAWINGS

FIG. 1 is a block diagram illustrating a configuration of an extended reality electronic device according to an embodiment of the present invention.

FIG. 2 is a perspective view of an augmented reality electronic device according to an embodiment of the present invention.

FIG. 3 is a perspective view of a projection device according to a first embodiment.

FIG. 4 is a cross-sectional view of the projection device according to the first embodiment.

FIGS. 5 and 6 are views illustrating the projection device according to the first embodiment.

FIG. 7 is a perspective view of a substrate, a light source unit, and a first prism in the projection device according to the first embodiment.

FIG. 8 is an exploded perspective view of the substrate, the light source unit, and the first prism in the projection device according to the first embodiment

FIG. 9 is a plan view of the substrate, the light source unit, and the first prism in the projection device according to the first embodiment.

FIG. 10 is a view taken along line A-A′ in FIG. 7.

FIG. 11 is a view taken along line B-B′ in FIG. 7.

FIGS. 12A to 12F are views illustrating a method of manufacturing the substrate, the light source unit, and the first prism in the projection device according to the first embodiment.

FIG. 13 is a cross-sectional view of a projection device according to a second embodiment.

FIG. 14 is a perspective view of a portion of the projection device according to the second embodiment.

FIG. 15 is a side view of FIG. 14.

FIG. 16 is a cross-sectional view of a light source and a first collimating member in the projection device according to the second embodiment.

FIGS. 17A-17D illustrate structures and heat maps of light intensity according to the presence or absence of the first collimating member.

FIGS. 18A and 18B illustrate graphs showing light intensity along horizontal and vertical lengths according to the presence or absence of the first collimating member of FIGS. 17A-17D.

FIGS. 19A-19D illustrate structures and heat maps of light intensity according to the presence or absence of the first collimating member.

FIGS. 20A and 20B illustrate graphs showing light intensity along horizontal and vertical lengths according to the presence or absence of the first collimating member of FIGS. 19A-19D.

FIG. 21 is a cross-sectional view of a projection device according to a third embodiment.

FIG. 22 is a view of some components in FIG. 21.

FIG. 23 is a cross-sectional view of a projection device according to a fourth embodiment.

FIG. 24 is a view of some components in FIG. 23.

### MODES OF THE INVENTION

Hereinafter, exemplary embodiments of the present invention will be described in detail with reference to the accompanying drawings.

However, the technical spirit of the present invention is not limited to some embodiments which will be described and may be implemented in various forms, and one or more elements in the embodiments may be selectively combined and replaced to be used within the scope of the technical spirit of the present invention.

Further, the terms used in the embodiments of the present invention (including technical and scientific terms), may be interpreted with meanings that are generally understood by those skilled in the art unless particularly defined and described, and terms which are generally used, such as terms defined in a dictionary, may be understood in consideration of their contextual meanings in the related art.

Further, the terms used in the embodiments of the present invention are provided only to describe embodiments of the present invention and not for purposes of limitation.

In the present specification, unless clearly indicated otherwise by the context, singular forms include the plural forms thereof, and in a case in which “at least one (or one or more) among A, B, and C” is described, this may include at least one combination among all combinations which can be combined with A, B, and C.

In addition, terms such as first, second, A, B, (a), (b), and the like may be used to describe components of the embodiments of the present invention.

These terms are only provided to distinguish the components from other components, and the essence, sequence, order, or the like of the components is not limited by the terms.

In addition, when a component is described as being “connected,” “coupled,” or “linked” to another component, the component may not only be directly connected, coupled, or linked to the other component but may also be “connected,” “coupled,” or “linked” to the other element by still another component between the component and the other component.

Further, when a component is described as being formed “on (above)” or “under (below)” another component, the term “on (above)” or “under (below)” includes both of a case in which the two components are in direct contact with each other and a case in which one or more components are (indirectly) disposed between the two components. In addition, when a component is described as being disposed “on (above) or under (below)” another component, such a description may include a case in which the component is disposed at an upper side or a lower side with respect to another component.

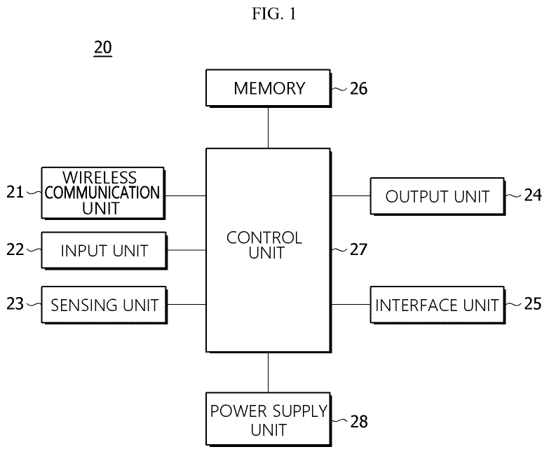

FIG. 1 is a block diagram illustrating a configuration of an extended reality electronic device according to an embodiment of the present invention.

Referring to FIG. 1, an extended reality electronic device 20 may include a wireless communication unit 21, an input unit 22, a sensing unit 23, an output unit 24, an interface unit 25, a memory 26, a control unit 27, a power supply unit 28, and the like. It is understood that implementing all the components illustrated in FIG. 1 is not a requirement for the electronic device 20, and that the electronic device 20 described in the present specification may be alternatively implemented by more or fewer components.

More specifically, among the above components, the wireless communication unit 21 may include one or more modules that allow wireless communication between the electronic device 20 and a wireless communication system, between the electronic device 20 and another electronic device, or between the electronic device 20 and an external server. Further, the wireless communication unit 21 may include one or more modules that connect the electronic device 20 to one or more networks.

The wireless communication unit 21 may include at least one of a broadcast receiving module, a mobile communication module, a wireless Internet module, a short-range communication module, and a position information module.

The input unit 22 may include a camera or an image input unit for receiving image signals, a microphone or an audio input unit for receiving audio signals, or a user input unit (for example, touch keys, push keys (mechanical keys), or the like) for receiving information from the user. Audio data or image data collected from the input unit 22 may be analyzed and processed by user control commands.

The sensing unit 23 may include one or more sensors for sensing at least one of internal information of the electronic device 20, information about a surrounding environment of the electronic device 20, and user information.

For example, the sensing unit 23 may include at least one of a proximity sensor, an illumination sensor, a touch sensor, an acceleration sensor, a magnetic sensor, a G-sensor, a gyroscope sensor, a motion sensor, an RGB sensor, an infrared (IR) sensor, a finger scan sensor, an ultrasonic sensor, an optical sensor (e.g., a capturing device), a microphone, a battery gauge, an environmental sensor (e.g., a barometer, a hygrometer, a thermometer, a radiation detection sensor, a thermal sensor, a gas sensor, or the like), and a chemical sensor (e.g., an electronic nose, a health care sensor, a biometric sensor, or the like). Meanwhile, the electronic device 20 described in the present specification may utilize a combination of information sensed from at least two or more of these sensors.

The output unit 24 may be configured to output various types of information related to vision, hearing, or tactile sensations, and may include at least one of a display unit, an audio output unit, a haptic module, or an optical output unit. The display unit may have an inter-layered structure or an integrated structure with a touch sensor to implement a touch screen. The touch screen may provide an output interface between the augmented reality electronic device 20 and the user, as well as function as a user input unit that provides an input interface between the augmented reality electronic device 20 and the user.

The interface unit 25 serves as an interface with various types of external devices that are connected to the electronic device 20. Through the interface unit 25, the electronic device 20 may receive virtual reality or augmented reality content from an external device, and perform mutual interaction by exchanging various input signals, sensing signals, and data.

For example, the interface unit 25 may include at least one of wired/wireless headset ports, external charger ports, wired/wireless data ports, memory card ports, ports for connecting a device having an identification module, audio input/output (I/O) ports, video input/output (I/O) ports, and earphone ports.

Further, the memory 26 stores data supporting various functions of the electronic device 20. The memory 26 may store a plurality of application programs or applications executed in the electronic device 20, and data or instructions for operations of the electronic device 20. At least some of these application programs may be downloaded from an external server via wireless communication. Further, at least some of these application programs may be present on the electronic device 20 at the time of shipment for basic functions (e.g., receiving a call, placing a call, receiving a message, and sending a message) of the electronic device 20.

The control unit 27 typically controls overall operations of the electronic device 20 in addition to the operations related to the application programs. The control unit 27 may process signals, data, information, and the like, which are input or output by the components described above.

In addition, the control unit 27 may execute an application stored in the memory 26 to control at least some of the components and provide appropriate information to the user or process functions. Furthermore, the control unit 27 may operate by combining at least two or more of components included in the electronic device 20 to execute the application program.

In addition, the control unit 27 may detect the movement of the electronic device 20 or the user using a gyroscope sensor, a gravity sensor, a motion sensor, and the like included in the sensing unit 23. Alternatively, the control unit 27 may detect objects approaching the electronic device 20 or the user using sensors such as a proximity sensor, a light sensor, a magnetic sensor, an infrared sensor, an ultrasonic sensor, or an optical sensor included in the sensing unit 23. In addition, the control unit 27 may also detect the movement of the user through sensors provided in a controller that operates in conjunction with the electronic device 20.

Further, the control unit 27 may perform operations (or functions) of the electronic device 20 using the application programs stored in the memory 26.

The power supply unit 28 receives external power and internal power and supplies the power to the respective components included in the electronic device 20 under the control of the control unit 27. The power supply unit 28 includes a battery, which may be provided in a built-in or replaceable form.

At least some of the respective components may operate in cooperation with one another to implement the operation, control, or control method of the electronic device according to various embodiments described below. Further, the operation, control, or control method of the electronic device may be implemented on the electronic device by execution of at least one application program stored in the memory 26.

Hereinafter, the electronic device described as an example of the present invention will be described based on an embodiment applied to head mounted displays (HMDs). However, the embodiments of the electronic device according to the present invention may also include devices such as mobile phones, smart phones, laptop computers, terminals for digital broadcasting, personal digital assistants (PDAs), portable multimedia players (PMPs), navigation systems, slate personal computers (PCs), tablet PCs, ultra books, and wearable devices. The wearable devices may include watch-type terminals (smartwatches), contact lenses, VR/AR/MR glasses, and the like in addition to the HMDs.

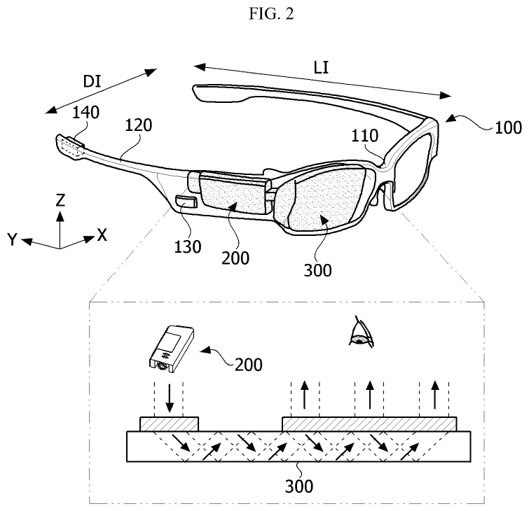

FIG. 2 is a perspective view of an augmented reality electronic device according to an embodiment of the present invention.

As shown in FIG. 2, the electronic device according to the embodiment of the present invention may include a frame 100, a projection device 200, and a display unit 300.

The electronic device may be provided as a glass type (smart glass). The glass-type electronic device may be configured to be worn on the head of the human body and may include the frame (a case, a housing, or the like) 100 therefor. The frame 100 may be formed of a flexible material to facilitate wearing.

The frame 100 is supported on the head and has a space in which various components are mounted. As illustrated in the drawing, electronic components such as the projection device 200, a user input unit 130, or an audio output unit 140 may be mounted on the frame 100. In addition, a lens covering at least one of a left eye and a right eye may be detachably mounted on the frame 100.

As illustrated in the drawing, the frame 100 may have the form of glasses worn on the face of the body of a user, but the present invention is not necessarily limited thereto, and the frame 100 may have the form such as goggles or the like, which are worn in close contact with the face of the user.

The frame 100 may include a front frame 110 having at least one opening and a pair of side frames 120 that extend in a y-direction (in FIG. 2) intersecting the front frame 110 and are parallel to each other.

The frame 100 may have a length DI in an x-direction (in FIG. 2) and a length LI in the y-direction (in FIG. 2), which may be the same as or different from each other.

The projection device 200 is provided to control various electronic components provided in the electronic device. The projection device 200 may be used interchangeably with a “light output device,” a “light projection device,” a “light irradiation device,” an “optical device,” and the like.

The projection device 200 may generate an image to be shown to the user or a video of continuous images. The projection device 200 may include an image source panel that generates an image and a plurality of lenses that diffuse and converge light generated from the image source panel.

The projection device 200 may be fixed to any one side frame 120 of two side frames 120. For example, the projection device 200 may be fixed to the inside or outside of any one side frame 120 or embedded and integrally formed in any one side frame 120. Alternatively, the projection device 200 may be fixed to the front frame 110 or provided separately from the electronic device.

The display unit 300 may be implemented in the form of an HMD. The HMD form refers to a display scheme that is mounted on the head and displays a video directly in front of the user's eyes. When the user wears the electronic device, the display unit 300 may be disposed to correspond to at least one of the left eye and the right eye to provide the video directly in front of the user's eye. In this drawing, it is illustrated that the display unit 300 is located at a part corresponding to the right eye to output the video toward the right eye of the user. However, as described above, the display unit 300 is not thereto and may be disposed in front of both the left and right eyes.

The display unit 300 may allow the image generated by the projection device 200 to be displayed to the user while the user visually recognizes an external environment. For example, the display unit 300 may project the image to a display area using a second prism.

In addition, the display unit 300 may be formed to be light-transmitting so that the projected image and a general field of view (a range visible to the user through their eyes) may be seen at the same time. For example, the display unit 300 may be semi-transparent and may be formed of an optical element including glass.

In addition, the display unit 300 may be inserted into and fixed to the opening included in the front frame 110 or located on a rear surface (i.e., between the opening and the user) of the opening to be fixed to the front frame 110. In the drawing, a case in which the display unit 300 is located on the rear surface of the opening and fixed to the front frame 110 is illustrated as an example, but unlike this, the display unit 300 may be disposed and fixed at various positions of the frame 100.

As shown in FIG. 2, in the electronic device, when image light from the projection device 200 for the image is incident on one side of the display unit 300, the image light is emitted to the other side through the display unit 300 to show the image generated by the projection device 200 to the user.

As a result, the user may view the image generated by the projection device 200 while simultaneously viewing the external environment through the opening of the frame 100. That is, the video output through the display unit 300 may appear to overlap the general field of view. The electronic device may provide augmented reality (AR) by overlaying a virtual image onto an image or background of reality using these display characteristics to show one image.

Furthermore, in addition to the above operation, the external environment and the image generated by the projection device 200 may be provided to the user with a time difference within a short period of time that is not perceivable by humans. For example, within one frame, the external environment may be provided to the user during one section, and the video from the projection device 200 may be provided to the user during another section.

Alternatively, both overlap and time difference may be provided.

In addition, a projection device according to a first embodiment may have a structure described below, or may be configured to further include a waveguide and/or a glass on the described structure. In addition, the projection device may include a digital light processing (DLP) projector or projection device.

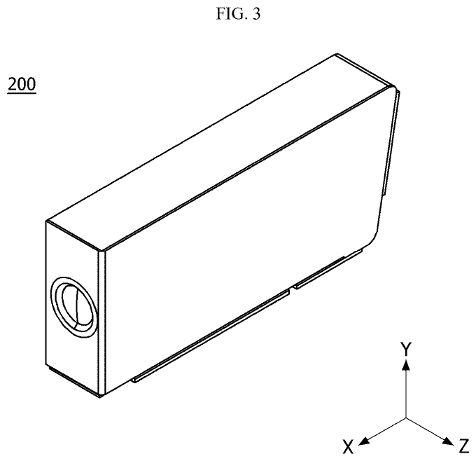

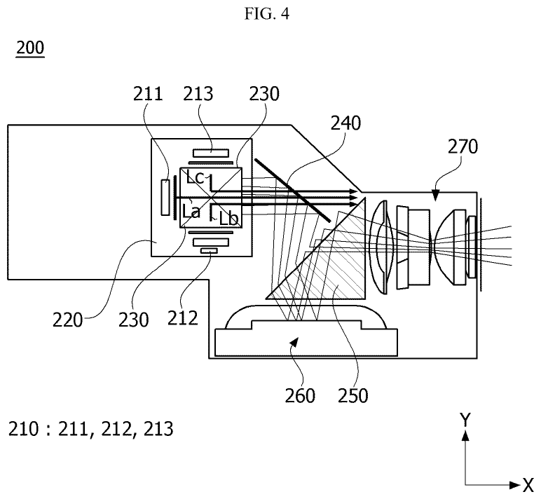

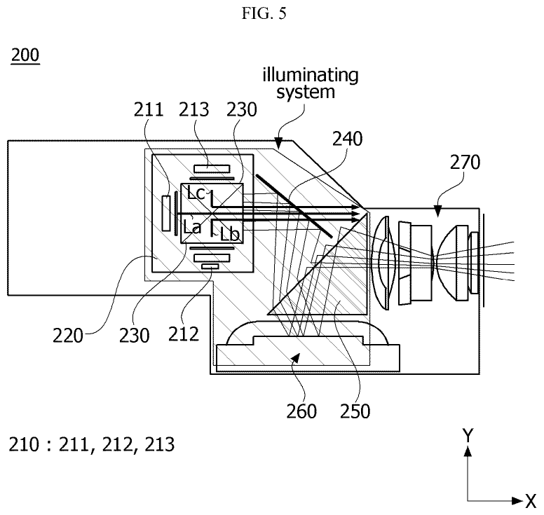

FIG. 3 is a perspective view of the projection device according to the first embodiment, FIG. 4 is a cross-sectional view of the projection device according to the first embodiment, and FIGS. 5 and 6 are views illustrating the projection device according to the first embodiment.

Referring to FIGS. 3 to 6, the projection device 200 according to the first embodiment may have a predetermined cover or housing. In addition, the projection device 200 may include each element, which will be described below, in the cover or housing. For example, the housing may have a space or housing groove in which each component of the projection device 200 is accommodated or disposed. The housing may be located on an outer side of the projection device 200. Other components may be disposed within the housing. For example, a light source unit 210, a substrate 220, a first prism 230, a reflection unit 240, a second prism 250, a light modulator 260, and a projection lens unit 270 may be disposed in the housing.

Further, the housing may have a structure that is open on one side. Accordingly, each of the components described above may be assembled through an open region or surface. Furthermore, a blocking member, which will be described below, may be disposed on the open region or surface of the housing.

The housing may have various shapes. For example, the housing may have a hexahedral structure. Accordingly, the projection device according to the first embodiment may be easily mounted on the electronic device. In addition, the projection device according to the first embodiment may be easily miniaturized or compacted.

More specifically, the projection device 200 according to the first embodiment may include the light source unit 210, the substrate 220, the first prism 230, the reflection unit 240, the second prism 250, the light modulator 260, and the projection lens unit 270. Furthermore, in the present specification, the term “rear end” includes the meaning of being located behind on a light path. Thus, the term “front end” includes the meaning of being located in front of a light path.

The light source unit 210 may emit light or illumination light. In an embodiment, the light source unit 210 may be disposed within the housing. The light source unit 210 may be disposed adjacent to any one of outer side surfaces of the housing.

The light source unit 210 may include at least one light source. In an embodiment, the light source unit 210 may emit light having different wavelength bands or colors through at least one panel. For example, illumination light, which is light emitted from the light source unit 210, may include light of a first wavelength band to a third wavelength band. For example, each of the first wavelength band, the second wavelength band, and the third wavelength band may correspond to one of red, green, and blue wavelength bands. Light of the first wavelength band may correspond to red (or green/blue) light. Light of the second wavelength band may correspond to green (or red/blue) light. Light of the third wavelength band may correspond to blue (or green/red) light. In addition, a central wavelength of light in a specific color wavelength band may correspond to a wavelength within the specific color wavelength band.

Specifically, in an embodiment, the light source unit 210 may include a first light source 211, a second light source 212, and a third light source 213. The first light source 211, the second light source 212, and the third light source 213 may be respectively located adjacent to different surfaces in the housing. The first light source 211, the second light source 212, and the third light source 213 may be disposed identically to or differently from the positions shown. In addition, the first light source 211, the second light source 212, and the third light source 213 may emit light in different wavelength bands or colors. For example, the first light source 211 may emit light (La) in the first wavelength band. In addition, the second light source 212 may emit light (Lb) in the second wavelength band. The third light source 213 may emit light (Lc) in the third wavelength band. For example, the first wavelength band, the second wavelength band, and the third wavelength band may respectively correspond to red, green, and blue wavelength bands. Light of the first wavelength band may correspond to red light. Light of the second wavelength band may correspond to green light. Light of the third wavelength band may correspond to blue light. In addition, a central wavelength of light in a specific color wavelength band may correspond to a wavelength within the specific color wavelength band. In addition, one side of each light source may have a size of several millimeters (mm). For example, the size may be from 0.5 mm to 2.0 mm.

Further, among the plurality of light sources included in the light source unit, the light source that emits light in a green wavelength band may be located between other light sources spaced apart from each other. For example, the first light source 211 may emit light in the green wavelength band. The second light source 212 may emit one of blue light and red light. The third light source 213 may emit the other of the blue light and the red light.

Further, a plurality of light beams from the light source unit 210 may be emitted in the same direction.

Further, the plurality of light sources may be disposed spaced apart from each other in a first direction or a second direction. For example, the first light source 211 may be disposed spaced apart from the second light source 212 and the third light source 213 in the first direction. In addition, the second light source 212 and the third light source 213 may be disposed spaced apart from each other in the second direction.

Further, in the projection device according to the first embodiment, the first direction may correspond to an “X-axis direction” in the drawings. The first direction may correspond to a direction from the light source unit 210 towards the projection lens unit 270. Alternatively, the first direction may correspond to a direction from the second prism 250 toward the projection lens unit 270. In addition, the second direction may correspond to a Y-axis direction in the drawings. The second direction may be a direction perpendicular to the first direction. A third direction may be a direction perpendicular to the first direction and the second direction. In addition, the third direction may correspond to a “Z-axis direction” in the drawings. The second direction may correspond to a direction of light emitted from the light modulator toward the second prism.

In addition, a plurality of light beams from the light source unit 210 may be emitted in the same direction. In other words, the plurality of light beams may be parallel to the emission direction.

In addition, the substrate 220 may be coupled to the first prism 230 and the light source unit 210. For example, both the light source unit 210 and the first prism 230 may be disposed on one surface of the substrate 220. In this regard, the projection device according to the first embodiment may not use a bent or curved substrate. In the miniaturized projection device, a phenomenon such as significant misalignment of the plurality of light sources due to bending of a small substrate may be suppressed. Furthermore, misalignment between the plurality of light sources and the first prism, which may occur when substrates in contact with the respective light sources are connected to each other, may be suppressed. As such, the projection device according to the first embodiment may provide precise alignment between the light sources and the first prism, thereby improving optical performance. Furthermore, fabrication of the miniaturized projection device and its components may be facilitated, and precise bonding between the components may be achieved. In other words, manufacturability may be improved. A detailed description thereof will be provided below.

The first prism 230 may be an X-cube or an X-plate. The first prism 230 may reflect or transmit light of different wavelength bands emitted from the light source unit 210 toward one outer side surface. That is, light incident on different outer side surfaces of the first prism 230 may be provided to the reflection unit 240 through one outer side surface. The first prism 230 may perform mixing of colors of different wavelength bands.

The first prism 230 may have a quadrilateral shape in cross-section. For example, the first prism 230 may have a square shape in cross-section. In addition, in a cross section of the first prism taken along the third direction or a direction perpendicular to the third direction, lengths of one side and another side may be different from each other. For example, a length of the first prism 230 in the third direction may be greater than a length of one side of a cross section perpendicular to the third direction.

In addition, one side of the outer side surface of the first prism 230 may have a length of several mm. For example, one side of the outer side surface of the first prism 230 may have a length of 0.75 mm to 6 mm. Preferably, one side of the outer side surface of the first prism 230 may have a length of 2.0 mm to 5.0 mm. The length of one side of the outer side surface of the first prism 230 may be greater than a length of one side of the light source. For example, the length of one side of the outer side surface of the first prism 230 may be 1.5 to 4 times the length of one side of the light source.

The reflection unit 240 may be disposed at the rear end of the first prism 230. The reflection unit 240 may be located on the side of the first prism 230 in the first direction (X-axis direction). The reflection unit 240 may be disposed spaced apart from the first prism 230 in the first direction. In addition, the reflection unit 240 may overlap the light source unit 210 or the first prism 230 in the first direction. Further, in the present embodiment, the light source unit 210, the first prism 230, and the reflection unit 240 may overlap each other along an optical axis. Here, the optical axis refers to a central axis of an illuminating system until light is incident on the reflection unit 240. In addition, the optical axis may be parallel to the first direction. In addition, compactness of the projection device may be achieved by the light source unit 210, the first prism 230, and the reflection unit 240 overlapping each other along the optical axis or the first direction.

In addition, the reflection unit 240 may be inclined at a predetermined angle with respect to the first prism 230. The reflection unit 240 may reflect light emitted from the first prism 230. For example, light that has passed through the first prism 230 may be reflected by the reflection unit 240, change its path toward the projection lens unit, and then be reflected toward a lower side or the light modulator. That is, the reflection unit 240 may change the light path.

The reflection unit 240 may be inclined at a predetermined angle with respect to the first prism 230, the first direction, or the like. With this configuration, a length of the projection device according to the first embodiment in the second direction may be minimized.

The second prism 250 may be disposed at the rear end of the reflection unit 240. In addition, the second prism 250 may be sequentially disposed with the reflection unit 240. The second prism 250 may be disposed between the reflection unit 240 and the light modulator 260. Furthermore, the second prism 250 may be located below the reflection unit 240. The second prism 250 and the reflection unit 240 may partially overlap each other in the second direction. Furthermore, a partial region of the second prism 250 may not overlap the reflection unit 240 in the second direction. In addition, at least a portion of the second prism 250 may not overlap the light source unit 210 and the first prism 230 in the second direction. The second prism 250 may be disposed between the light modulator 260 and the projection lens unit 270. In addition, the second prism 250 may be disposed between the reflection unit 240 and the light modulator 260. With this configuration, the second prism 250 may transmit light emitted from (or transmitted through) the reflection unit 240, and may reflect the light incident on and re-emitted from the light modulator 260 toward the projection lens unit 270.

The second prism 250 may include a total internal reflection (TIR) second prism. As described above, the second prism 250 may change a traveling direction of light rays. That is, the second prism 250 may perform transmission and reflection of light rays. Specifically, the second prism 250 may transmit light emitted from (or transmitted through) the reflection unit 240 and reflect light emitted from the light modulator 260. In addition, the second prism 250 may transmit light emitted from the light source unit 210 and reflect light emitted from the light modulator 260. Thus, the path of light may be changed toward the first direction or the projection lens unit. With this configuration, miniaturization of the projection device according to the first embodiment may be achieved.

The light modulator 260 may be disposed at the rear end of the second prism 250. The light modulator 260 may emit the light transmitted through the second prism 250 back to the second prism 250.

The light modulator 260 may reflect incident light to project an image. For example, the light modulator 260 may emit or project a video or image based on an image signal incident through a substrate. That is, the light modulator 260 may modulate light emitted from the light source unit 210.

The light modulator 260 according to the embodiment may include a digital micromirror device (DMD). In addition, the light modulator 260 may include a light modulation device such as a liquid crystal on silicon (LCOS). The light modulator 260 may include a plurality of micromirrors. In addition, each mirror may reflect or block light in response to a signal (e.g., a digital signal). In other words, the light modulator 260 may control the state of each mirror based on an image signal applied through the substrate, and may project an image corresponding to the image signal. For example, when light is reflected by controlling the mirror, a bright region of the image may be displayed, and when light is blocked, a dark region of the image may be displayed.

Further, the second direction (Y-axis direction) may correspond to a direction perpendicular to an upper surface of the light modulator 260. For example, the light modulator 260 may have a diagonal length of several inches or less. The diagonal length of the light modulator 260 may be 0.15 inches or more and 2.0 inches or less. Accordingly, the diagonal length may be easily modified for miniaturization or for achieving size implementation of an image or a light guide device.

The projection lens unit 270 may be disposed at the rear end of the second prism 250. When light emitted from the light modulator 260 is reflected by the second prism 250, the reflected light may be incident on the projection lens unit 270. The above-described light may be projected through the projection lens unit 270. The projection lens unit 270 may project the light emitted from the projection device onto a screen or light guide (or the display unit).

In an embodiment, the projection lens unit 270 may adjust the size of the image so that light rays enter through an entrance pupil diameter (EPD) of the waveguide or the like.

To this end, the projection lens unit 270 according to the embodiment may include a lens barrel and a plurality of lenses (or an optical system) disposed in the lens barrel.

The plurality of lenses may at least partially overlap the second prism 250 in the first direction.

The blocking member (not shown) may be disposed on one outer side surface of the housing. Accordingly, the blocking member may be disposed on the outer side of each component after the components are accommodated in the housing. In an embodiment, the blocking member may be disposed on one side of the housing corresponding to a groove of the housing. In addition, the blocking member may cover each component. With this configuration, the blocking member may easily block foreign substances or stray light from entering the components of the housing. Accordingly, image projection of the electronic device or the projection device may be more accurately implemented.

Further, the light source unit 210, the first prism 230, and the reflection unit 240 may be sequentially disposed in one direction or along the optical axis. In addition, the second prism 250 and the projection lens unit 270 may be sequentially disposed in another direction. Here, the one direction and the other direction may be misaligned (e.g., perpendicular) or parallel to each other. When the one direction and the other direction are misaligned (e.g., perpendicular), a length of the projection device in the one direction may be reduced. In addition, when the one direction and the other direction are parallel to each other, the one direction (or the other direction) may be aligned with an extending direction of the side frame of the electronic device. Accordingly, the projection device may be easily mounted or seated in the frame of the electronic device.

Further, the reflection unit 240 may at least partially overlap the second prism 250 in the second direction (Y-axis direction). In addition, the reflection unit 240 may at least partially overlap the light modulator 260 in the second direction (Y-axis direction). The light modulator 260 may at least partially overlap the second prism 250 in the second direction. Accordingly, a projection device with improved optical efficiency and facilitated miniaturization may be provided.

Furthermore, the reflection unit 240 may also partially overlap the second prism 250 in the first direction. Accordingly, a space for coupling between the second prism 250 and the housing may be secured. In addition, support strength for the reflection unit 240 may be improved. Further, the length in the second direction may be reduced, thereby achieving miniaturization.

Referring further to FIGS. 5 and 6, the projection device according to the first embodiment may include an illuminating system and a projecting system (also referred to as a projection system, a projecting unit, a projection unit, a projecting part, or the like).

The projection device may include an illuminating system. According to the embodiment, the illuminating system may include the light source unit 210, the first prism 230, the reflection unit 240, and the second prism 250. That is, light provided from the second prism 250 may be incident on the light modulator 260.

The illuminating system may include the second prism 250 as a component thereof, receive light (illumination light) from the light source, and emit the light in a predetermined direction. The illumination light may be delivered or provided to the light modulator 260 of the projecting system.

Referring further to FIG. 6, the projecting system may include the second prism 250, the light modulator 260, and the projection lens unit 270. The projecting system may include the second prism 250 as a component. In an embodiment, the second prism 250 may be an element of both the illuminating system and the projecting system.

Furthermore, the projecting system may further include the above-described illuminating system. That is, the projecting system may modulate the illumination light generated by the illuminating system through the light modulator 260, and emit or radiate the modulated light in a predetermined direction through the second prism 250 and the projection lens unit 270.

The light modulator 260 may reflect illumination light as patterned light or the like, and the patterned light may pass through the projection lens unit 270 and may be output to the outside of the projection device.

In addition, an optical folding member may be present between an output unit of the projection device and an input unit of a waveguide or wavelength guide. The optical folding member may be formed such that an optical path of the patterned light is folded in at least two different directions. In addition, the display unit may have various structures, and through such various structures, the display unit may receive light emitted from the projection device and provide the light to a user.

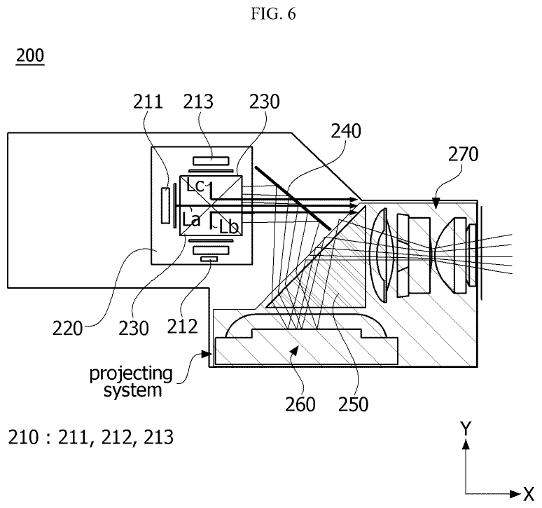

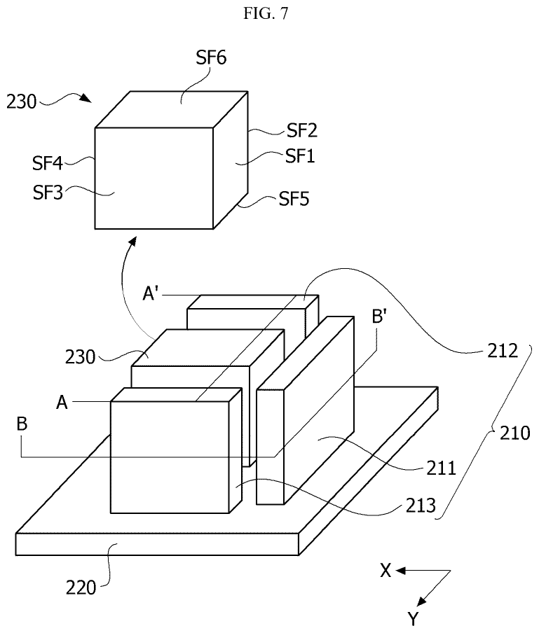

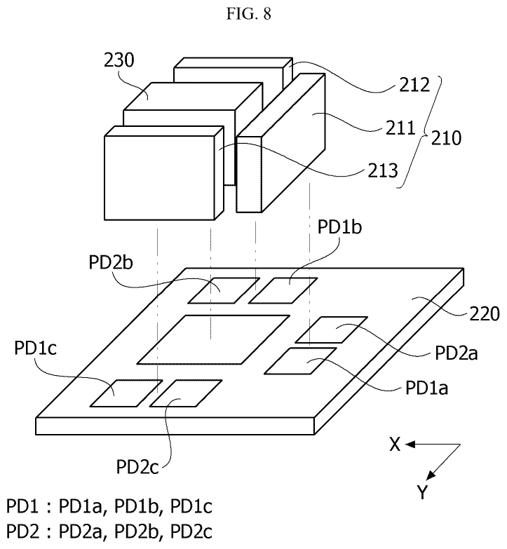

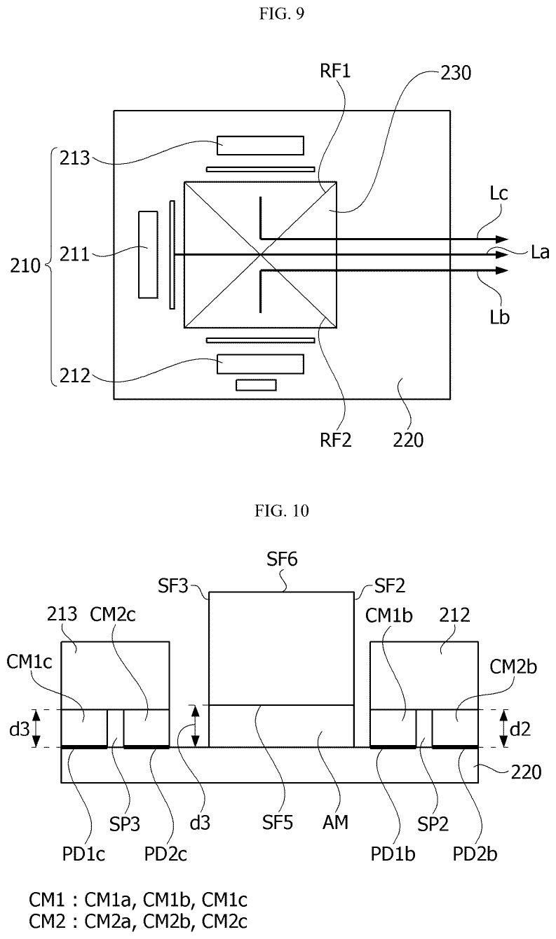

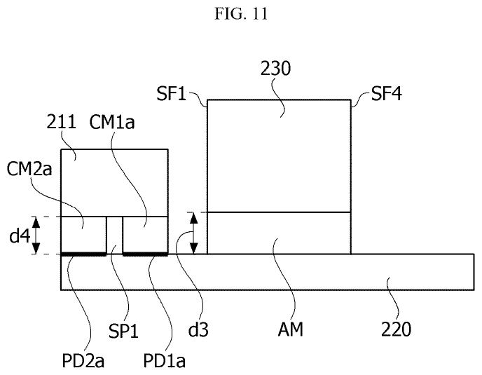

FIG. 7 is a perspective view of the substrate, the light source unit, and the first prism in the projection device according to the first embodiment, FIG. 8 is an exploded perspective view of the substrate, the light source unit, and the first prism in the projection device according to the first embodiment, FIG. 9 is a plan view of the substrate, the light source unit, and the first prism in the projection device according to the first embodiment, FIG. 10 is a view taken along A-A′ in FIG. 7, and FIG. 11 is a view taken along line B-B′ in FIG. 7.

Referring to FIGS. 7 to 11, the plurality of light sources 211, 212, and 213 (or the light source unit) described above may include the first light source 211, the second light source 212, and the third light source 213.

In addition, the outer side surfaces of the first prism 230 may include a first outer side surface SF1 to a third outer side surface SF3 that face the respective light sources 211, 212, and 213. The first outer side surface SF1 may face the first light source 211. The second outer side surface SF2 may face the second light source 212. The third outer side surface SF3 may face the third light source unit 230c. Alternatively, the first light source 211 may correspond to the first outer side surface SF1. The second light source 212 may correspond to the second outer side surface SF2. The third light source 213 may correspond to the third outer side surface SF3.

Further, the outer side surfaces of the first prism 230 may include a fourth outer side surface SF4. The fourth outer side surface SF4 may be an outer side surface facing the reflection unit 240. In addition the fourth outer side surface SF4 may correspond to the reflection unit 240.

In addition, the outer side surfaces of the first prism 230 may include a fifth outer side surface SF5 and a sixth outer side surface SF6. The fifth outer side surface SF5 and the sixth outer side surface SF6 may be outer side surfaces of the first prism 230 other than the first outer side surface SF1 to the fourth outer side surface SF4.

The first outer side surface SF1 may correspond to the fourth outer side surface SF4 in the first prism 230. For example, the first outer side surface SF1 may face the fourth outer side surface SF4 in the first prism 230. The second outer side surface SF2 may correspond to the third outer side surface SF3 in the first prism 230. For example, the second outer side surface SF2 may face the third outer side surface SF3 in the first prism 230. The fifth outer side surface SF5 may correspond to the sixth outer side surface SF6 in the first prism 230. For example, the fifth outer side surface SF5 may face the sixth outer side surface SF6 in the first prism 230.

In various examples, a masking layer may be located at an edge of the outer side surface of the first prism 230. For example, the masking layer may be formed or located at the edge of each outer side surface. The masking layer may be formed on a portion of the outer side surface of the first prism 230 other than a region with an effective diameter or an effective region. The masking layer may be formed in various ways using an opaque material, such as printing, black painting (including black pigment), or a sheet (e.g., Soma sheet). In addition, the masking layer may be formed of a material having low transmittance. Thus, unintended total internal reflection may be reduced or suppressed. In addition, flare and ghost phenomena may be reduced or inhibited. In addition, an effect of reducing optical aberration or the like may be provided.

Furthermore, the first prism 230 may be connected to the substrate 220 in a state in which an optical member (e.g., a lens) is attached thereto. Optical performance may be improved through such an optical member.

In addition, the first outer side surface SF1, the second outer side surface SF2, and the third outer side surface SF3 of the first prism 230 may be incident surfaces of light. The fourth outer side surface SF4 of the first prism 230 may be an emission surface of light. Accordingly, the fourth outer side surface SF4 of the first prism 230 may face the reflection unit 240. Thus, the reflection unit 240 may be disposed at the rear end of the first prism 230, and light transmitted through or emitted from the first prism 230 may be reflected by the reflection unit 240 and provided to the light modulator 260.

In addition, the first prism 230 and the light source unit 210 may be disposed on one surface of the substrate 220. In other words, the first prism 230 and the light source unit 210 may be disposed on the same one of the outer side surfaces of the substrate 220. For example, the first prism 230 and the light source unit 210 may be disposed on an upper surface of the substrate 220.

On the upper surface of the substrate 220, the plurality of light sources 211, 212, and 213 may surround the first prism 230. For example, on the upper surface of the substrate 220, the first light source 211 may face the first outer side surface SF1 of the first prism 230. In addition, on the upper surface of the substrate 220, the second light source 212 may face the second outer side surface SF2 of the first prism 230. In addition, on the upper surface of the substrate 220, the third light source 213 may face the third outer side surface SF3 of the first prism 230. Accordingly, the fourth outer side surface SF4 may not be in contact with the upper surface of the substrate 220. In addition, any one of the fifth outer side surface SF5 and the sixth outer side surface SF6 may be in contact with the upper surface of the substrate 220. That is, among the outer side surfaces of the first prism 230, the outer side surface on which light is not incident or from which light is not emitted may be in contact with or may face the upper surface of the substrate 220. For example, the fifth outer side surface SF5 may face the upper surface of the substrate 220. In addition, a distance between the fifth outer side surface SF5 and the upper surface of the substrate 220 may be smaller than a distance between the sixth outer side surface SF6 and the upper surface of the substrate 220.

Furthermore, the plurality of light sources 211, 212, and 213 of the light source unit may emit light toward the first prism 230. A direction of light emission from the light source unit 210 may be perpendicular to a direction perpendicular to the upper surface of the substrate 220. In addition, for the plurality of light sources 211, 212, and 213, a surface perpendicular to a light emission surface may face the upper surface of the substrate 220. In addition, the plurality of light sources 211, 212, and 213 may be bonded to the substrate through a surface other than the surface facing the emission surface.

In addition, the substrate 220 according to the embodiment may include pad portions PD1 and PD2. The pad portions PD1 and PD2 may be exposed on the upper surface of the substrate 220. The pad portions PD1 and PD2 may overlap the plurality of light sources.

The pad portions PD1 and PD2 may include a first pad PD1 and a second pad PD2. Each of the plurality of light sources may be electrically connected to the first pad PD1 and the second pad PD2. For example, the first pad PD1 and the second pad PD2 may be electrically connected to a positive electrode (or a negative electrode) and a negative electrode (or a positive electrode), respectively.

In an embodiment, the first pad PD1 may include a 1-1 pad PD1a, a 1-2 pad PD1b, and a 1-3 pad PD1c. The 1-1 pad PD1a, the 1-2 pad PD1b, and the 1-3 pad PD1c may be respectively connected to the first light source 211, the second light source 212, and the third light source 213. The second pad PD2 may include a 2-1 pad PD2a, a 2-2 pad PD2b, and a 2-3 pad PD2c. In the second pad PD2, the 2-1 pad PD2a, the 2-2 pad PD2b, and the 2-3 pad PD2c may be respectively connected to the first light source 211, the second light source 212, and the third light source 213. That is, the first light source 211 may be connected to the 1-1 pad PD1a and the 2-1 pad PD2a. The second light source 212 may be connected to the 1-2 pad PD1b and the 2-2 pad PD2b. The third light source 213 may be connected to the 1-3 pad PD1c and the 2-3 pad PD2c.

In addition, the projection device may include conductive portions CM1 and CM2. The conductive portions CM1 and CM2 may be located between the pad portions PD1 and PD2 and the light source unit. The conductive portions CM1 and CM2 may include a first conductive member CM1 and a second conductive member CM2. The first conductive member CM1 may be disposed between the first pad PD1 and the light sources. The second conductive member CM2 may be disposed between the second pad PD2 and the light sources. In addition, the conductive portions CM1 and CM2 may be formed of a conductive material such as conductive epoxy. For example, the conductive portions CM1 and CM2 may include electrically conductive adhesives (ECA), Ag epoxy (conductive epoxy), epoxy solder paste (low reflow temperature) (ESP), or the like.

In addition, each of the plurality of light sources may be electrically connected to the first conductive member CM1 and the second conductive member CM2. Further, the first conductive member CM1 may be connected to the first pad PD1. In addition, the second conductive member CM2 may be connected to the second pad PD2. Accordingly, the first conductive member CM1 and the second conductive member CM2 may be electrically connected to the positive electrode (or the negative electrode) and the negative electrode (or the positive electrode), respectively.

In an embodiment, the first conductive member CM1 may include a 1-1 conductive member CMla, a 1-2 conductive member CM1b, and a 1-3 conductive member CM1c. The 1-1 conductive member CMla, the 1-2 conductive member CM1b, and the 1-3 conductive member CM1c may be respectively connected to the first light source 211, the second light source 212, and the third light source 213. The second conductive member CM2 may include a 2-1 conductive member CM2a, a 2-2 conductive member CM2b, and a 2-3 conductive member CM2c. In the second conductive member CM2, the 2-1 conductive member CM2a, the 2-2 conductive member CM2b, and the 2-3 conductive member CM2c may be respectively connected to the first light source 211, the second light source 212, and the third light source 213. That is, the first light source 211 may be connected to the 1-1 conductive member CMla and the 2-1 conductive member CM2a. The second light source 212 may be connected to the 1-2 conductive member CM1b and the 2-2 conductive member CM2b. The third light source 213 may be connected to the 1-3 conductive member CM1c and the 2-3 conductive member CM2c. The 1-1 conductive member CMla may be disposed between the first light source 211 and the 1-1 pad PD1a. The 2-1 conductive member CM2a may be disposed between the first light source 211 and the 2-1 pad PD2a. The 1-2 conductive member CM1b may be disposed between the second light source 212 and the 1-2 pad PD1b. The 2-2 conductive member CM2b may be disposed between the second light source 212 and the 2-2 pad PD2b. The 1-3 conductive member CM1c may be disposed between the third light source 213 and the 1-3 pad PD1c. The 2-3 conductive member CM2c may be disposed between the third light source 213 and the 2-3 pad PD2c.

Further, the projection device may include spacers SP1, SP2, and SP3. The spacers SP1, SP2, and SP3 may be disposed between the first conductive member CM1 and the second conductive member CM2. The spacers SP1, SP2, and SP3 may inhibit electrical connections between the first conductive member CM1 and the second conductive member CM2. Thus, electrical reliability of the projection device may be improved.

In addition, the plurality of light sources 211, 212, and 213 may be in contact with the spacers SP1, SP2, and SP3. With this configuration, electrical reliability may be further enhanced.

The spacers SP1, SP2, and SP3 may include a first spacer SP1, a second spacer SP2, and a third spacer SP3. The first spacer SP1 may be disposed between the 1-1 conductive member CMla and the 2-1 conductive member CM2a. The second spacer SP2 may be disposed between the 1-2 conductive member CM1b and the 2-2 conductive member CM2b. The third spacer SP3 may be disposed between the 1-3 conductive member CM1c and the 2-3 conductive member CM2c. Accordingly, electrical reliability may be improved while ensuring support strength for each light source.

Further, the projection device according to the first embodiment may include an adhesive member AM disposed on the substrate 220. The adhesive member AM may be in contact with the fifth outer side surface SF5 of the first prism 230. For example, the adhesive member AM may be disposed between the fifth outer side surface SF5 and the upper surface of the substrate 220. The adhesive member AM may be formed of an adhesive material. For example, the adhesive member AM, which is a film-type adhesive member such as an optically clear adhesive (OCA), may be disposed. Thus, the adhesive member may provide excellent workability, and manufacturability may be improved by being uniformly adhered to the surface.

In an embodiment, a height d3 of the adhesive member AM may be greater than each of distance d1, d2, and d4 between the light source unit 210 and the upper surface of the substrate 220. In addition, the height d3 of the adhesive member AM may be different from each of the heights d1, d2, and d4 of the first conductive member CM1 or the second conductive member CM2. For example, the height d3 of the adhesive member AM may be greater than each of the heights d1, d2, and d4 of the first conductive member CM1 or the second conductive member CM2.

In addition, an upper surface of the first prism 230 may be disposed above upper surfaces of the plurality of light sources 211, 212, and 213. For example, the sixth outer side surface SF6 of the first prism 230 may be located above the upper surfaces of the plurality of light sources 211, 212, and 213. With this configuration, light may be incident on the first prism 230 without loss. Accordingly, the projection device according to the first embodiment may provide improved optical efficiency.

Further, the spacer may be further disposed between the first prism 230 and the substrate 220. Accordingly, a height difference between the first prism 230 and the plurality of light sources 211, 212, and 213 may be easily adjusted.

In addition, the plurality of light sources 211, 212, and 213 may be disposed at the same or similar height from the upper surface of the substrate 220. For example, the similar height may refer to a tolerance within +5%. That is, the separation distances d3, d2, and d4 between the light sources 211, 212, and 213 and the upper surface of the substrate 220 may be the same. In addition, heights of the conductive portions CM1 and CM2 may also be the same. With this configuration, positional alignment among the plurality of light sources 211, 212, and 213 may be achieved more accurately. In other words, the plurality of light sources 211, 212, and 213 may be connected on the same surface of the substrate 220, and the conductive portions CM1 and CM2 may have the same height, thereby allowing easy fixation of positions of the plurality of light sources on a plane.

In another example, the plurality of light sources on the substrate 220 may be coupled by a wire or the like, instead of the pad portions and the conductive portions. Similarly, the sixth outer side surface SF6 of the first prism may be located above the upper surfaces of the plurality of light sources.

Additionally, the substrate 220 may further include an alignment mark formed on the upper surface. The alignment mark may be disposed not only on the substrate 220 but also on the first prism 230 or the plurality of light sources. With this configuration, positional alignment between the first prism 230 and the plurality of light sources 211, 212, and 213 on the upper surface of the substrate 220 may be performed more accurately. Accordingly, optical performance may be improved.

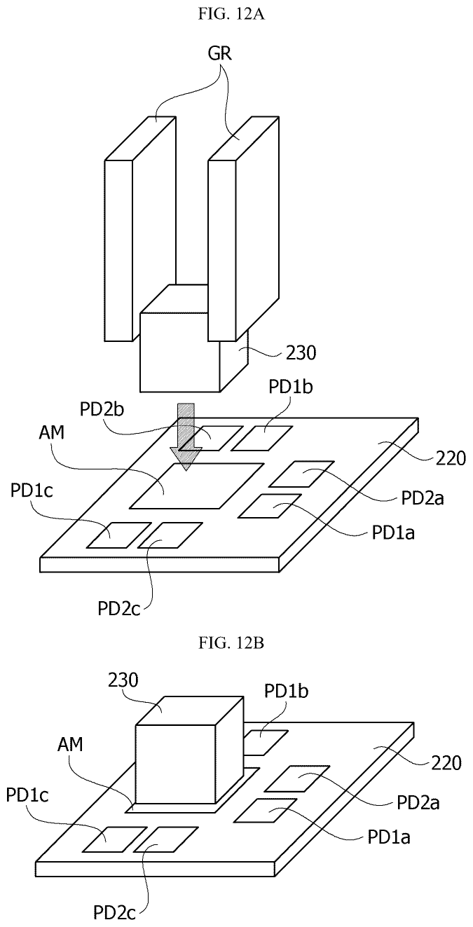

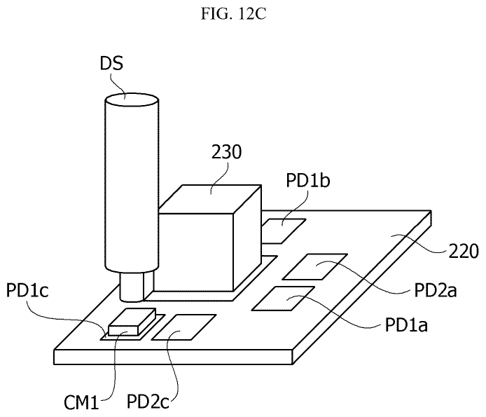

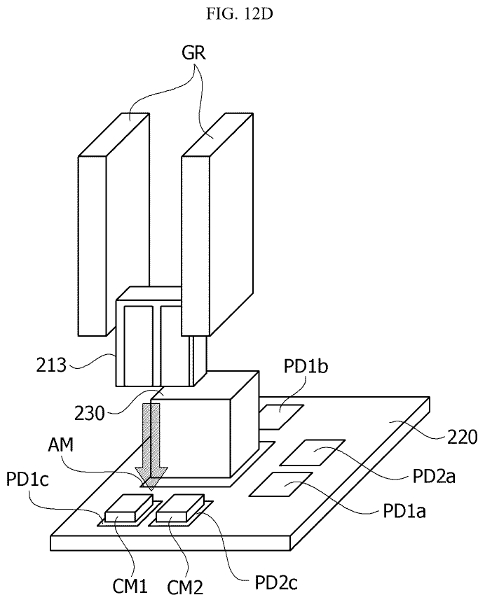

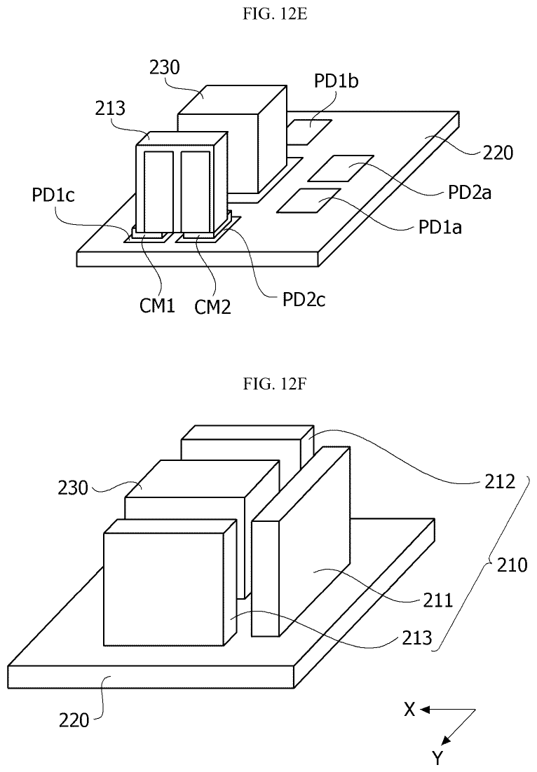

FIGS. 12A to 12F are views illustrating a method of manufacturing the substrate, the light source unit, and the first prism in the projection device according to the first embodiment.

Referring to FIG. 12A, an adhesive member AM may be applied on a substrate 220. In addition, the adhesive member AM on an upper surface of the substrate 220 may be surrounded by pad portions.

Referring to FIG. 12B, a first prism 230 may be located on the adhesive member AM by equipment such as die bonding. Accordingly, the first prism 230 may be attached to the adhesive member AM.

Referring to FIG. 12C, conductive members may be applied on the pad portions. For example, a first conductive member may be applied on a first pad, and a second conductive member may be applied on a second pad.

Referring to FIG. 12D, light sources may be located on the respective conductive members by equipment such as die bonding. Accordingly, a plurality of light sources may be respectively attached to the conductive members.

Furthermore, each spacer may be attached in a state of being bonded to each light source, or may be located between the first conductive member and the second conductive member. The spacer may be provided on the upper surface of the substrate before or after applying the first conductive member and the second conductive member.

Referring to FIG. 12E, the applying of the conductive member and the attaching of the light source may be repeatedly performed for the plurality of light sources.

Referring to FIG. 12F, by attaching each of the plurality of light sources to the upper surface of the substrate, each light source may surround the first prism 230. Furthermore, without a small mechanism for fixing a small optical component such as the first prism or a reflective mirror (e.g., a dichroic mirror), the light sources and the first prism may be more easily aligned on the substrate by die-bonding equipment. Furthermore, the substrate 220 does not require a bent structure, and thus an occurrence of optical axis alignment errors due to bending may be suppressed.

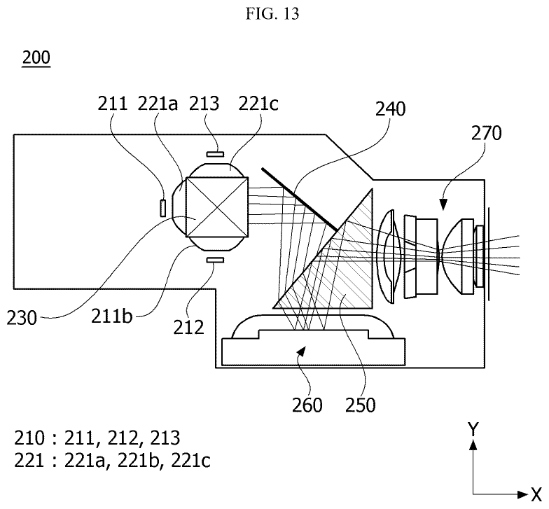

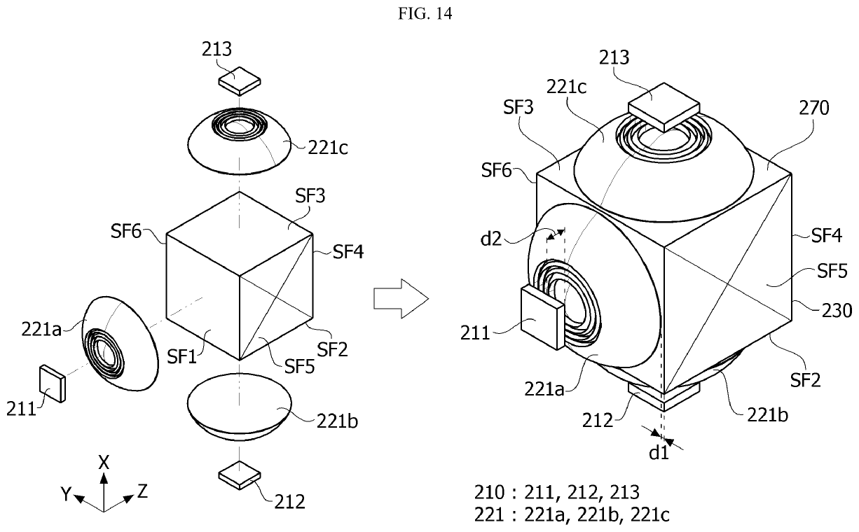

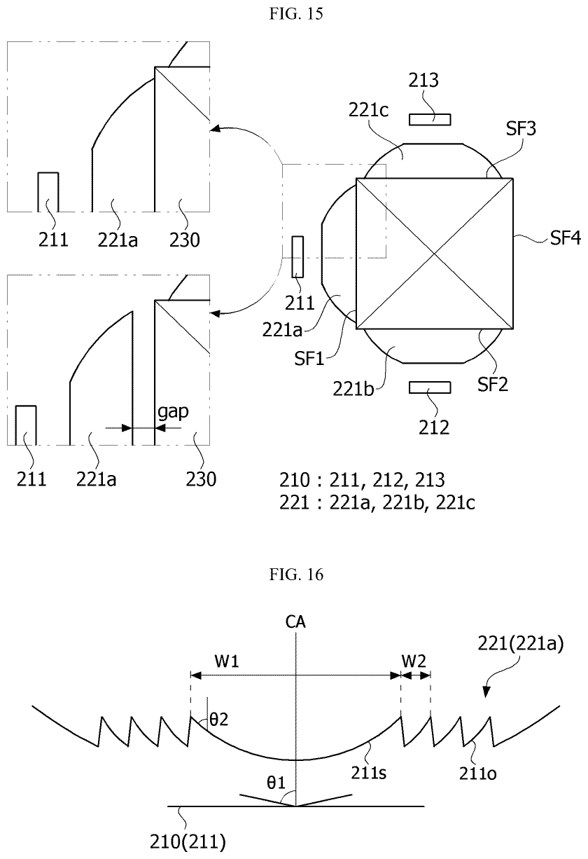

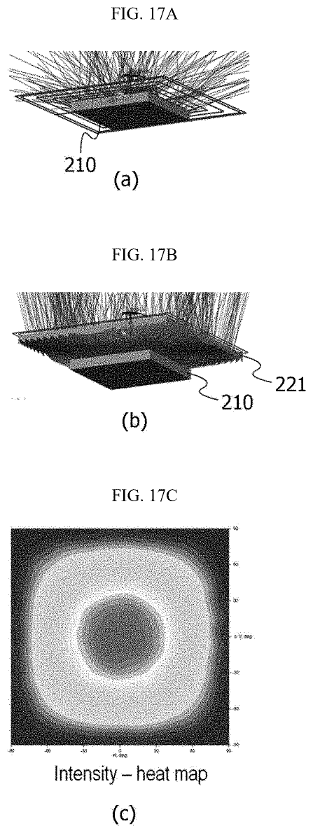

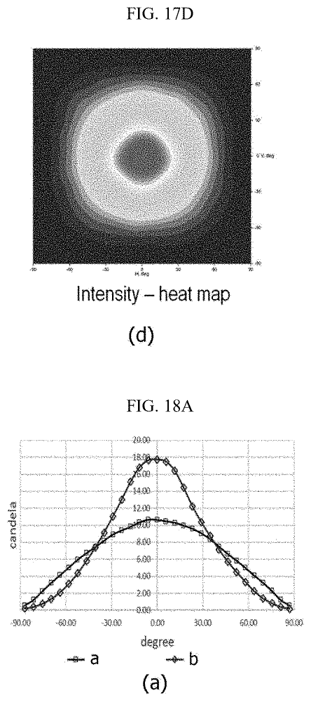

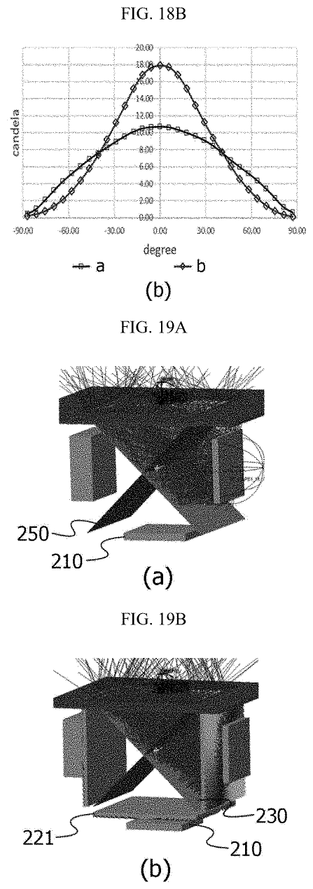

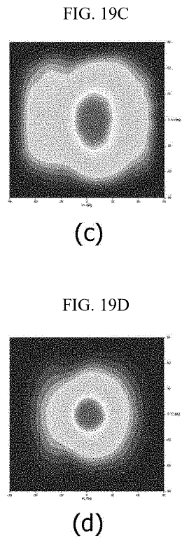

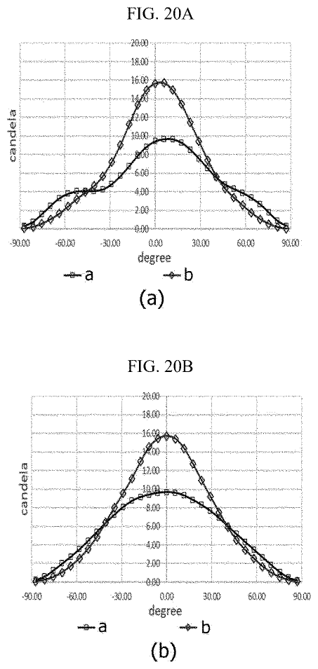

FIG. 13 is a cross-sectional view of a projection device according to a second embodiment, FIG. 14 is a perspective view of a portion of the projection device according to the second embodiment, FIG. 15 is a side view of FIG. 14, FIG. 16 is a cross-sectional view of a light source and a first collimating member in the projection device according to the second embodiment, FIGS. 17A-17D illustrate structures and heat maps of light intensity according to the presence or absence of the first collimating member, FIGS. 18A and 18B illustrate graphs showing light intensity along horizontal and vertical lengths according to the presence or absence of the first collimating member of FIGS. 17A-17D, FIGS. 19A-19D illustrate structures and heat maps of light intensity according to the presence or absence of the first collimating member, and FIGS. 20A and 20B illustrate graphs showing light intensity along horizontal and vertical lengths according to the presence or absence of the first collimating member of FIGS. 19A-19D.

Referring to FIGS. 13 to 15, a projection device 200 according to the embodiment may have a predetermined cover or housing. In addition, the projection device 200 may include each element, which will be described below, within the cover or housing. For example, the housing may have a space or housing groove in which each component of the projection device 200 is accommodated or disposed. The housing may be located on an outer side of the projection device 200. Other components may be disposed within the housing. For example, a light source unit 210, a first collimating member 221, a first prism 230, a reflection unit 240, a second prism 250, a light modulator 260, and a projection lens unit 270 may be disposed in the housing.

Further, the housing may have a structure that is open on one side. Accordingly, each of the components described above may be assembled through an open region or surface. Furthermore, a blocking member, which will be described below, may be disposed on the open region or surface of the housing.

The housing may have various shapes. For example, the housing may have a hexahedral structure. Accordingly, the projection device according to the embodiment may be easily mounted on the electronic device. In addition, the projection device according to the embodiment may be easily miniaturized or compacted.

More specifically, the projection device 200 according to the second embodiment may include the light source unit 210, the first collimating member 221, the first prism 230, the reflection unit 240, the second prism 250, the light modulator 260, and the projection lens unit 270. Furthermore, in the present specification, the term “rear end” includes the meaning of being located behind on a light path. Thus, the term “front end” includes the meaning of being located in front of a light path.

The light source unit 210 may emit light or illumination light. In an embodiment, the light source unit 210 may be disposed within the housing. The light source unit 210 may be disposed adjacent to any one of outer side surfaces of the housing.

The light source unit 210 may include at least one light source. In an embodiment, the light source unit 210 may emit light having different wavelength bands or colors through at least one panel. For example, illumination light, which is light emitted from the light source unit 210, may include light of a first wavelength band to a third wavelength band. For example, the first wavelength band, the second wavelength band, and the third wavelength band may respectively correspond to red, green, and blue wavelength bands. Light of the first wavelength band may correspond to red (or green/blue) light. Light of the second wavelength band may correspond to green (or red light/blue) light. Light of the third wavelength band may correspond to blue (or green/red) light. In addition, a central wavelength of light in a specific color wavelength band may correspond to a wavelength within the specific color wavelength band.

Specifically, in an embodiment, the light source unit 210 may include a first light source 211, a second light source 212, and a third light source 213. The first light source 211, the second light source 212, and the third light source 213 may be respectively located adjacent to different surfaces within the housing. The first light source 211, the second light source 212, and the third light source 213 may be disposed identically to or differently from the positions shown. In addition, the first light source 211, the second light source 212, and the third light source 213 may emit light in different wavelength bands or colors. For example, the first light source 211 may emit light in the first wavelength band. In addition, the second light source 212 may emit light in the second wavelength band. The third light source 213 may emit light in the third wavelength band. For example, the first wavelength band, the second wavelength band, and the third wavelength band may respectively correspond to red, green, and blue wavelength bands. Light of the first wavelength band may correspond to red light. Light of the second wavelength band may correspond to green light. Light of the third wavelength band may correspond to blue light. In addition, a central wavelength of light in a specific color wavelength band may correspond to a wavelength within the specific color wavelength band.

In addition, one side of each light source may have a size of several mm. For example, the size may be from 0.5 mm to 1.5 mm. In addition, as described above, at least some of the plurality of light sources may be disposed on the substrate. For example, the substrate may be a flexible printed circuit board. Accordingly, the plurality of light sources may be disposed on the substrate, and the substrate may be bent such that the light sources surround the first prism.

Further, among the plurality of light sources included in the light source unit, the light source that emits light in a green wavelength band may be located between other light sources spaced apart from each other. For example, the first light source 211 may emit light in the green wavelength band. The second light source 212 may emit one of blue light and red light. The third light source 213 may emit the other of the blue light and the red light.

In addition, a plurality of light beams from the light source unit 210 may be emitted in the same direction.

Further, the plurality of light sources may be disposed spaced apart from each other in a first direction or a second direction. For example, the first light source 211 may be disposed spaced apart from the second light source 212 and the third light source 213 in the first direction. In addition, the second light source 212 and the third light source 213 may be disposed spaced apart from each other in the second direction.

Further, in the projection device according to the embodiment, the first direction may correspond to an “X-axis direction” in the drawings. The first direction may correspond to a direction from the light source unit 210 towards the projection lens unit 270. Alternatively, the first direction may correspond to a direction from the second prism 250 toward the projection lens unit 270. In addition, the second direction may correspond to a Y-axis direction in the drawings. The second direction may be a direction perpendicular to the first direction. A third direction may be a direction perpendicular to the first direction and the second direction. In addition, the third direction may correspond to a “Z-axis direction” in the drawings. The second direction may correspond to a direction of light emitted from the light modulator toward the second prism.

In addition, a plurality of light beams from the light source unit 210 may be emitted in the same direction. In other words, the plurality of light beams may be parallel to the emission direction.

In addition, the collimating member may be disposed at the front end of the first prism 230 or at the rear end of the first prism 230. In the present embodiment, the collimating member may include the first collimating member 221 located at the front end of the first prism 230.

The first collimating member 221 may be located at the rear ends of the plurality of light sources of the light source unit 210. In addition, the first collimating member 221 may be located between the plurality of light sources of the light source unit 210 and the first prism 230.

The first collimating member 221 may include at least one of a Fresnel lens, a TIR Fresnel lens, a micro lens array (MLA), and a meta lens.

The first collimating member 221 may be formed of a material such as glass or plastic. Furthermore, the first collimating member 221 may have one side with a length of several mm and a height of 0.5 mm to 1.5 mm or less. For example, the first collimating member 221 may have one side with a length of 0.75 mm to 6 mm corresponding to the first prism.

The first prism 230 may be located at the rear end of the first collimating member 221. The first prism 230 may be disposed adjacent to the first collimating member 221. The first prism 230 may overlap the first collimating member 221 in one direction (e.g., the first direction).

The first prism 230 may be an X-cube or an X-plate. The first prism 230 may reflect or transmit light of different wavelength bands emitted from the light source unit 210 toward one outer side surface. That is, light incident on different outer side surfaces of the first prism 230 may be provided to the reflection unit 240 through one outer side surface. The first prism 230 may perform mixing of colors of different wavelength bands.

The first prism 230 may have a quadrilateral shape in cross-section. For example, the first prism 230 may have a square shape in cross-section. In addition, in a cross section of the first prism taken along the third direction or a direction perpendicular to the third direction, lengths of one side and another side may be different from each other. For example, a length of the first prism 230 in the third direction may be greater than a length of one side of a cross section perpendicular to the third direction.

In addition, one side of the outer side surface of the first prism 230 may have a length of several mm. For example, one side of the outer side surface of the first prism 230 may have a length of 0.75 mm to 6 mm. The length of one side of the outer side surface of the first prism 230 may be greater than a length of one side of the light source. For example, the length of one side of the outer side surface of the first prism 230 may be 1.5 to 4 times the length of one side of the light source.

The reflection unit 240 may be disposed at the rear end of the first prism 230. The reflection unit 240 may be located on the side of the first prism 230 in the first direction (X-axis direction). The reflection unit 240 may be disposed spaced apart from the first prism 230 in the first direction. In addition, the reflection unit 240 may overlap the light source unit 210, the first collimating member 221, or the first prism 230 in the first direction. Further, in the present embodiment, the light source unit 210, the first collimating member 221, the first prism 230, and the reflection unit 240 may overlap each other along an optical axis. Here, the optical axis refers to a central axis of an illuminating system until light is incident on the reflection unit 240. In addition, the optical axis may be parallel to the first direction. In addition, compactness of the projection device may be achieved by the light source unit 210, the first collimating member 221, the first prism 230, and the reflection unit 240 overlapping each other along the optical axis or the first direction. In particular, the size of the illuminating system may be reduced and light uniformity may be improved by the first collimating member 221.

In addition, the reflection unit 240 may be inclined at a predetermined angle with respect to the first prism 230. The reflection unit 240 may reflect light emitted from the first prism 230. For example, light that has passed through the first prism 230 may be reflected by the reflection unit 240, change its path toward the projection lens unit, and then be reflected toward a lower side or the light modulator. That is, the reflection unit 240 may change the light path.

The reflection unit 240 may be inclined at a predetermined angle with respect to the first prism 230, the first direction, or the like. With this configuration, a length of the projection device according to the embodiment in the second direction may be minimized.

The second prism 250 may be disposed at the rear end of the reflection unit 240. In addition, the second prism 250 may be sequentially disposed with the reflection unit 240. The second prism 250 may be disposed between the reflection unit 240 and the light modulator 260. Furthermore, the second prism 250 may be located below the reflection unit 240. The second prism 250 and the reflection unit 240 may partially overlap each other in the second direction. Furthermore, a partial region of the second prism 250 may not overlap the reflection unit 240 in the second direction. In addition, at least a portion of the second prism 250 may not overlap the light source unit 210, the first collimating member 221, and the first prism 230 in the second direction. The second prism 250 may be disposed between the light modulator 260 and the projection lens unit 270. In addition, a second prism 250 may be disposed between the reflection unit 240 and the light modulator 260. With this configuration, the second prism 250 may transmit light emitted from (or transmitted through) the reflection unit 240, and may reflect the light incident on and re-emitted from the light modulator 260 toward the projection lens unit 270.

The second prism 250 may include a TIR second prism. As described above, the second prism 250 may change a traveling direction of light rays. That is, the second prism 250 may perform transmission and reflection of light rays. Specifically, the second prism 250 may transmit light emitted from (or transmitted through) the reflection unit 240 and reflect light emitted from the light modulator 260. In addition, the second prism 250 may transmit light emitted from the light source unit 210 and reflect light emitted from the light modulator 260. Thus, the path of light may be changed toward the first direction or the projection lens unit. With this configuration, miniaturization of the projection device according to the embodiment may be achieved.

The light modulator 260 may be disposed at the rear end of the second prism 250. The light modulator 260 may emit the light transmitted through the second prism 250 back to the second prism 250.

The light modulator 260 may reflect incident light to project an image. For example, the light modulator 260 may emit or project a video or image based on an image signal incident through a substrate. That is, the light modulator 260 may modulate light emitted from the light source unit 210.

The light modulator 260 according to the embodiment may include a digital micromirror device (DMD). The light modulator 260 may include a plurality of micromirrors. In addition, each mirror may reflect or block light in response to a signal (e.g., a digital signal). In other words, the light modulator 260 may control the state of each mirror based on an image signal applied through the substrate, and may project an image corresponding to the image signal. For example, when light is reflected by controlling the mirror, a bright region of the image may be displayed, and when light is blocked, a dark region of the image may be displayed.

Further, the second direction (Y-axis direction) may correspond to a direction perpendicular to an upper surface of the light modulator 260. For example, the light modulator 260 may have a diagonal length of several inches or less. The diagonal length of the light modulator 260 may be 0.15 inches or more and 2.0 inches or less. Accordingly, the diagonal length may be easily modified for miniaturization or for achieving size implementation of an image or a light guide device.

The projection lens unit 270 may be disposed at the rear end of the second prism 250. When light emitted from the light modulator 260 is reflected by the second prism 250, the reflected light may be incident on the projection lens unit 270. The above-described light may be projected through the projection lens unit 270. The projection lens unit 270 may project the light emitted from the projection device onto a screen or light guide (or the display unit).

In an embodiment, the projection lens unit 270 may adjust the size of the image so that light rays enter through an entrance pupil diameter (EPD) of the waveguide or the like.

To this end, the projection lens unit 270 according to the embodiment may include a lens barrel and a plurality of lenses (or an optical system) disposed in the lens barrel.

The plurality of lenses may at least partially overlap the second prism 250 in the first direction.

The blocking member (not shown) may be disposed on one outer side surface of the housing. Accordingly, the blocking member may be disposed on the outer side of each component after the components are accommodated in the housing. In an embodiment, the blocking member may be disposed on one side of the housing corresponding to a groove of the housing. In addition, the blocking member may cover each component. With this configuration, the blocking member may easily block foreign substances or stray light from entering the components of the housing. Accordingly, image projection of the electronic device or the projection device may be more accurately implemented.

Further, the light source unit 210, the first collimating member 221, the first prism 230, and the reflection unit 240 may be sequentially disposed in one direction or along the optical axis. In addition, the second prism 250 and the projection lens unit 270 may be sequentially disposed in another direction. Here, the one direction and the other direction may be misaligned (e.g., perpendicular) or parallel to each other. When the one direction and the other direction are misaligned (e.g., perpendicular), a length of the projection device in the one direction may be reduced. In addition, when the one direction and the other direction are parallel to each other, the one direction (or the other direction) may be aligned with an extending direction of the side frame of the electronic device. Accordingly, the projection device may be easily mounted or seated in the frame of the electronic device.

The first collimating member 221 may at least partially overlap the reflection unit 240 and the second prism 250 in the first direction (X-axis direction). Accordingly, the length of the projection device in the second direction (Y-axis direction) may be reduced. Thus, miniaturization of the projection device may be more easily implemented.

Further, a length of the first collimating member 221 in the second direction may be smaller than a length of the reflection unit 240 in the second direction. Accordingly, reflection efficiency for light emitted through the first collimating member 221 may be improved.

Further, the reflection unit 240 may at least partially overlap the second prism 250 in the second direction (Y-axis direction). In addition, the reflection unit 240 may at least partially overlap the light modulator 260 in the second direction (Y-axis direction). The light modulator 260 may at least partially overlap the second prism 250 in the second direction. Accordingly, a projection device with improved optical efficiency and facilitated miniaturization may be provided.

Furthermore, the reflection unit 240 may also partially overlap the second prism 250 in the first direction. Accordingly, a space for coupling between the second prism 250 and the housing may be secured. In addition, support strength for the reflection unit 240 may be improved. Further, the length in the second direction may be reduced, thereby achieving miniaturization.

Furthermore, the projection device according to the embodiment may include an illuminating system and a projecting system (also referred to as a projection system, a projecting unit, a projection unit, a projecting part, or the like).

The projection device may include an illuminating system. According to the embodiment, the illuminating system may include the light source unit 210, the first collimating member 221, the first prism 230, the reflection unit 240, and the second prism 250. That is, light provided from the second prism 250 may be incident on the light modulator 260.

The illuminating system may include the second prism 250 as a component thereof, receive light (illumination light) from the light source, and emit the light in a predetermined direction. The illumination light may be delivered or provided to the light modulator 260 of the projecting system.

Referring further to FIG. 13, the projecting system may include the second prism 250, the light modulator 260, and the projection lens unit 270. The projecting system may include the second prism 250 as a component. In an embodiment, the second prism 250 may be an element of both the illuminating system and the projecting system.

Furthermore, the projecting system may further include the above-described illuminating system. That is, the projecting system may modulate the illumination light generated by the illuminating system through the light modulator 260, and emit or radiate the modulated light in a predetermined direction through the second prism 250 and the projection lens unit 270.

The light modulator 260 may reflect illumination light as patterned light or the like, and the patterned light may pass through the projection lens unit 270 and may be output to the outside of the projection device.

In addition, an optical folding member may be present between an output unit of the projection device and an input unit of a waveguide or wavelength guide. The optical folding member may be formed such that an optical path of the patterned light is folded in at least two different directions. In addition, the display unit may have various structures, and through such various structures, the display unit may receive light emitted from the projection device and provide the light to a user.

More specifically, the plurality of light sources 211, 212, and 213 (or the light source unit) described above may include the first light source 211, the second light source 212, and the third light source 213.

In addition, the outer side surfaces of the first prism 230 may include a first outer side surface SF1 to a third outer side surface SF3 that face the respective light sources 211, 212, and 213. The first outer side surface SF1 may face the first light source 211. The second outer side surface SF2 may face the second light source 212. The third outer side surface SF3 a third light source unit 230c. Alternatively, the first light source 211 may correspond to the first outer side surface SF1. The second light source 212 may correspond to the second outer side surface SF2. The third light source 213 may correspond to the third outer side surface SF3.

Further, the outer side surfaces may include a fourth outer side surface SF4. The fourth outer side surface SF4 may be an outer side surface facing the reflection unit 240. In addition, the fourth outer side surface SF4 may correspond to the reflection unit 240.

Further, the outer side surfaces may include a fifth outer side surface SF5 and a sixth outer side surface SF6. The fifth outer side surface SF5 and the sixth outer side surface SF6 may be outer side surfaces of the first prism 230 other than the first outer side surface SF1 to the fourth outer side surface SF4.

The first outer side surface SF1 may correspond to the fourth outer side surface SF4 in the first prism 230. For example, the first outer side surface SF1 may face the fourth outer side surface SF4 in the first prism 230. The second outer side surface SF2 may correspond to the third outer side surface SF3 in the first prism 230. For example, the second outer side surface SF2 may face the third outer side surface SF3 in the first prism 230. The fifth outer side surface SF5 may correspond to the sixth outer side surface SF6 in the first prism 230. For example, the fifth outer side surface SF5 may face the sixth outer side surface SF6 in the first prism 230.

A masking layer may be located at an edge of the outer side surface of the first prism 230. For example, the masking layer may be formed or located at the edge of each outer side surface. The masking layer may be formed on a portion of the outer side surface of the first prism 230 other than a region with an effective diameter or an effective region. The masking layer may be formed in various ways with an opaque material, such as printing, black painting (including black pigment), or a sheet (e.g., Soma sheet). In addition, the masking layer may be formed of a material having low transmittance. Thus, unintended total internal reflection may be reduced or suppressed. In addition, flare and ghost phenomena may be reduced or inhibited. In addition, an effect of reducing optical aberration or the like may be provided.

The first collimating member 221 may include a plurality of collimating members 221a to 221c. For example, the first collimating member 221 may include a 1-1 collimating member 221a, a 1-2 collimating member 221b, and a 1-3 collimating member 221c corresponding to the light source unit.

Furthermore, the 1-1 collimating member 221a may be located between the first outer side surface SF1 and the first light source 211. The 1-2 collimating member 221b may be located between the second outer side surface SF2 and the second light source 212. The 1-3 collimating member 221c may be located between the third outer side surface SF3 and the third light source 213.

Alternatively, the 1-1 collimating member 221a may be located adjacent to the first outer side surface SF1. The 1-2 collimating member 221b may be located adjacent to the second outer side surface SF2. The 1-3 collimating member 221c may be located adjacent to the third outer side surface SF3.

In an embodiment, the first collimating member 221 may be in contact with or spaced apart from each outer side surface. For example, the 1-1 collimating member 221a may be in contact with or spaced apart from the first outer side surface SF1. The 1-2 collimating member 221b may be in contact with or spaced apart from the second outer side surface SF2. The 1-3 collimating member 221c may be in contact with or spaced apart from the third outer side surface SF3.

In an embodiment, a first separation distance d1 between the first collimating member 221 and the first prism 230 may be smaller than a second separation distance d2 between the first collimating member 221 and the plurality of light sources. With this configuration, a volume of the illuminating system in the projection device may be minimized. That is, miniaturization may be easily achieved.

For example, the distance between the first collimating member 221 and the light source unit 210 may be 0.5 mm to 1.5 mm. For example, the separation distance between the light source unit 210 and the first collimating member 221 may be less than or equal to a length of one side of the light source.

The first collimating member 221 may be located between each light source and the first prism 230. The first collimating member 221 may guide light provided from the light source to the first prism 230 through total internal reflection and refraction. The first collimating member 221 may inhibit light emitted from the light source unit 210 from being scattered to surrounding regions. Accordingly, light transmission efficiency may be improved. The first collimating member 221 may be formed of poly(methyl methacrylate) (PMMA), an acrylic material, or a glass material. However, the present invention is not limited thereto.

Referring further to FIG. 16, in various examples, the first collimating member 221 may include a central portion 211s and a sawtooth portion 2110. The central portion 211S may be disposed in a central region of the first collimating member 221. The central portion 211S may have a shape similar to that of a general convex lens. For example, a central axis of the central portion 211S may overlap a central axis of the first outer side surface SF1 (or the fourth outer side surface) of the first prism 230.

In addition, the sawtooth portion 2110 may be disposed around the central portion 211S. The sawtooth portion 2110 may surround the central portion 211S, and a width W2 thereof may be constant, or the width W2 may decrease outward from the central portion 211S.

In addition, a width W1 of the central portion 211S may be greater than the width W2 of on pattern in the sawtooth portion 2110.

Furthermore, the sawtooth portion 2110 may have an arc shape surrounding the central portion 211S. The arc of the sawtooth portion 2110 may increase as it moves away from the central portion 211S. The sawtooth portion 2110 may be composed of a plurality of patterns (e.g., teeth) and may have a structure symmetrical with respect to a central point of the central portion 211S. In an embodiment, the sawtooth portion 2110 may have a shape protruding toward the first prism 230. In addition, the central portion 211S may have a convex structure toward the light source unit 210.

In addition, the sawtooth portion 2110 may guide light incident from the light source unit 210 to the first prism 230 through total internal reflection and refraction.

By the first collimating member 221, a collimating lens having a large size, a large width, and a large separation distance from the light source does not need to be disposed at the rear end of the light source unit. Thus, the size of the projection device may be significantly reduced.

Further, the first collimating member 221 may reduce a radiation angle of light incident on the first prism 230. For example, the first collimating member 221 may reduce the radiation angle of light incident on the first prism 230 from 40 to 80 degrees to 10 to 30 degrees (01->02). With this configuration, a divergence angle of light emitted from the light source unit or the light source may be reduced, and a central luminous intensity of rays may be increased. For example, the central luminous intensity may be increased by two times or more by the first collimating member 221.

Furthermore, an area of the first collimating member 221 may be larger than an area of the outer side surface of the first prism 230 facing the first collimating member 221. For example, an area of the 1-1 collimating member 221a may be larger than that of the first outer side surface SF1 of the first prism 230 In addition, an area of the 1-2 collimating member 221b may be larger than that of the second outer side surface SF2 of the first prism 230. An area of the 1-3 collimating member 221c may be larger than that of the third outer side surface SF3 of the first prism 230. With this configuration, optical efficiency may be improved.

Referring to FIGS. 17A-17D, FIG. 17A illustrates a structure in which only the light source unit 210 is present and the first collimating member 221 is absent. FIG. 17B illustrates a structure in which both the light source unit 210 and the first collimating member 221 are present. FIG. 17C is a heat map of light intensity of light emitted from FIG. 17A. FIG. 17D is a heat map of light intensity of light emitted from FIG. 17B.

When comparing FIGS. 17C and 17D, it can be seen that a divergence angle of light emitted from the light source unit 210 decreases as the light passes through the first collimating member 221. Accordingly, an incident angle on the first prism may be reduced. Thus, a decrease in reflection and transmission efficiency at an internal boundary surface of the first prism may be inhibited (for example, red and blue light are reflected while green light is transmitted). Furthermore, it can be seen that luminous intensity is concentrated at the center of the light source unit 210 by the first collimating member 221. Accordingly, the first collimating member 221 may reduce the incident angle on the first prism and improve overall optical efficiency.

Referring to FIGS. 18A and 18B, FIG. 18A illustrates light intensity along a vertical length in case (a) in which the first collimating member is absent and case (b) in which the first collimating member is present. FIG. 18B illustrates light intensity according to a horizontal length for case (a) in which the first collimating member is absent and case (b) in which the first collimating member is present.

As shown in Table 1 and FIGS. 18A and 18B, it can be seen that luminous intensity is concentrated at the center of the light source unit 210 in both vertical and horizontal directions by the first collimating member 221. Accordingly, the first collimating member 221 may further improve overall optical efficiency.

TABLE 1

| | Light source (e.g., blue LED) | | | |
|---|---|---|---|---|
| | | | Light source & first | |
| | Only light source | | collimating member | |
| | (FIG. 17A) | | (FIG. 17B) | |
| | Presence or absence of first collimating member | | | |
| | Absent | | Present | |
| Item | Value | Ratio | Value | Ratio |
| Total lumen | 30.81 | 100% | 28.60 | 93.0% |
| Peak intensity | 10.68 | 100% | 17.90 | 168.0% |
| FWHM | 112.82 | 100% | 71.71 | 64.0% |

Referring to FIGS. 19A-19D, FIG. 19A illustrates a structure in which the first collimating member 221 is absent between the light source unit 210 and the first prism 230. FIG. 19B illustrates a structure in which the first collimating member 221 is present between the light source unit 210 and the first prism 230. FIG. 19C is a heat map of light emitted through the fourth outer side surface of the first prism 230 from FIG. 19A. FIG. 19D is a heat map of light emitted through the fourth outer side surface of the first prism 230 from FIG. 19B. When comparing FIGS. 19C and 19D, it can be seen that a divergence angle of light emitted from the light source unit 210 decreases as the light passes through the first collimating member 221. Accordingly, an incident angle on the first prism may be reduced. Thus, a decrease in reflection and transmission efficiency at an internal boundary surface of the first prism may be inhibited (for example, red and blue light are reflected while green light is transmitted). Furthermore, it can be seen that luminous intensity is concentrated at the center of the light source unit 210 by the first collimating member 221. Accordingly, the first collimating member 221 may reduce an incident angle on the first prism and improve overall optical efficiency. Referring to FIGS. 20A and 20B, FIG. 20A illustrates light intensity along a vertical length for case (a) in which the first collimating member is absent and case (b) in which the first collimating member is present. FIG. 20B illustrates light intensity along a horizontal length for case (a) in which the first collimating member is absent and case (b) in which the first collimating member is present.

As shown in Table 2 and FIGS. 20A and 20B, it can be seen that luminous intensity is concentrated at the center of the light source unit 210 in both vertical and horizontal directions by the first collimating member 221. Accordingly, the first collimating member 221 may further improve overall optical efficiency.

TABLE 2

| | Light source (e.g., blue LED) | | | | | |
|---|---|---|---|---|---|---|
| | Only light source | | Light source and | | Light source, first collimating member, | |
| | (FIG. 17A) | | first prism | | and first prism | |
| | Presence or absence of first collimating member | | | | | |
| | Absent | | Absent | | Present | |
| Item | Value | Ratio | Value | Ratio | Value | Ratio |
| Total | 30.81 | 100% | 21.59 | 70% | 22.10 | 72% |
| lumen | | | | | | |
| Peak | 10.68 | 100% | 9.65 | 90% | 15.70 | 147% |
| intensity | | | | | | |
| FWHM | 112.82 | 100% | 86.86 | 77% | 64.30 | 57% |

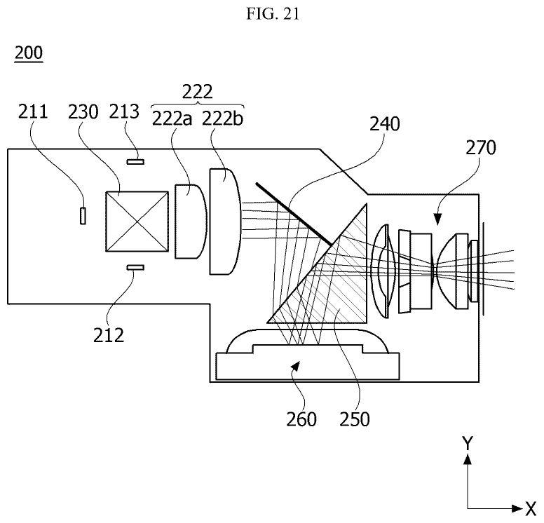

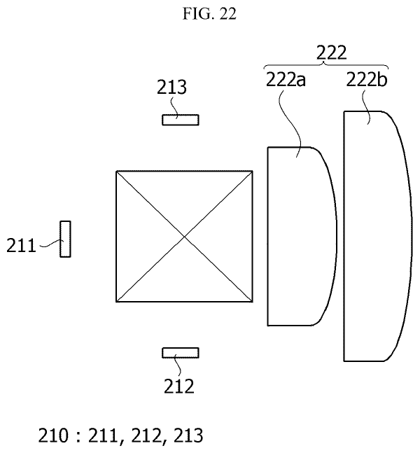

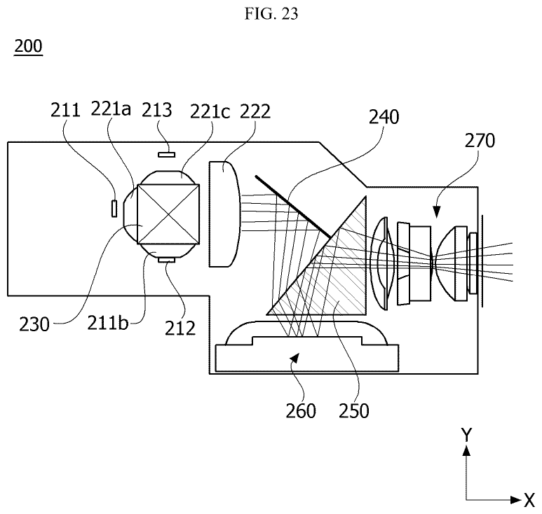

FIG. 21 is a cross-sectional view of a projection device according to a third embodiment, and FIG. 22 is a view of some components in FIG. 21. Referring to FIGS. 21 and 22, a projection device 200 according to the third embodiment may include a light source unit 210, a first prism 230, a second collimating member 222, a reflection unit 240, a second prism 250, a light modulator 260, and a projection lens unit 270. Furthermore, in the present specification, the term “rear end” includes the meaning of being located behind on a light path. Thus, the term “front end” includes the meaning of being located in front of a light path. Unlike the above-described embodiments, the projection device according to the present embodiment may include the second collimating member 222. The second collimating member 222 may be located at the rear end of the first prism 230. In addition, the second collimating member 222 may be located between the first prism 230 and the reflection unit 240. The second collimating member 222 may be located to face a fourth outer side surface of the first prism 230. In addition, the second collimating member 222 may overlap the first prism 230 and the reflection unit 240 in the first direction.

The second collimating member 222 may include a collimating lens. The second collimating member 222 may include at least one lens. For example, the second collimating member 222 may include a plurality of lenses. The second collimating member 222 may include a 2-1 collimating member 222a and a 2-2 collimating member 222b. The 2-2 collimating member 222b may be located at the rear end of the 2-1 collimating member 222a.

Furthermore, the second collimating member 222 may have a greater length than the first prism 230 in the second direction and in the third direction.

In addition, by not disposing collimator lenses at rear ends of respective light sources, and instead disposing the second collimating member, which is a collimating lens, at the rear end of the first prism in the form of an x-cube, miniaturization of the projection device may be more easily achieved. In addition, rather than performing collimation when optical axes of different colors are different or somewhat separated, collimation may be performed by the second collimating member in a state in which the optical axes are coincident or close to each other through the first prism. Accordingly, design of the optical system may become easier.

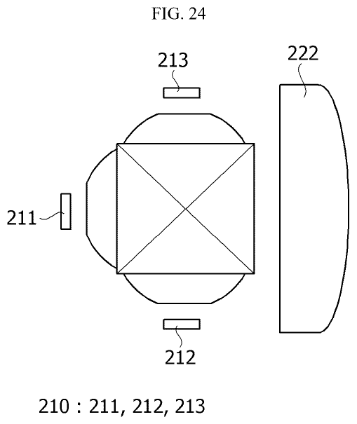

FIG. 23 is a cross-sectional view of a projection device according to a fourth embodiment, and FIG. 24 is a view of some components in FIG. 23.

Referring to FIGS. 23 and 24, a projection device 200 according to the fourth embodiment may include a light source unit 210, a first collimating member 221, a first prism 230, a second collimating member 222, a reflection unit 240, a second prism 250, a light modulator 260, and a projection lens unit 270. Furthermore, in the present specification, the term “rear end” includes the meaning of being located behind on a light path. Thus, the term “front end” includes the meaning of being located in front of a light path.

Except for contents described below, the above-described contents may be equally applied. The projection device according to the present embodiment may include both the first collimating member 221 disposed at the front end of the first prism 230 and the second collimating member 222 disposed at the rear end of the first prism 230. With this configuration, a radiation angle of light from a light source may be reduced and luminous intensity may be concentrated at the center by the first collimating member 221. Furthermore, since light that is primarily collimated by the first collimating member 221 is incident on the first prism 230 and transmitted through a fourth outer side surface, a structure of the second collimating member 222 may be made smaller and simplified. Furthermore, the collimating effect may be doubled.

Features, structures, effects, and the like described in the above embodiments are included in at least one embodiment, and are not necessarily limited to only one embodiment. Furthermore, features, structures, effects, and the like illustrated in each embodiment can be combined or modified for other embodiments by those of ordinary skill in the art to which the embodiments belong. Accordingly, the contents related to such combinations and modifications should be interpreted as being included in the scope of the embodiments.

Although the embodiments have been described above, the embodiments are merely examples and not intended to limit the present invention and it may be seen that a variety of modifications and applications not described above may be made by one of ordinary skill in the art without departing from the essential features of the embodiments. For example, each component specifically shown in the embodiment may be implemented with modifications. In addition, it should be construed that differences related to such changes and applications are included in the scope of the embodiments defined in the appended claims.

1. A projection device comprising:
a plurality of light sources configured to emit light and spaced apart from each other;
a first prism facing the plurality of light sources;
a light modulator configured to modulate the light;
a reflection unit disposed at a rear end of the first prism and configured to reflect the light transmitted through the first prism toward the light modulator;
a second prism disposed between the light modulator and the reflection unit;
a projection lens unit on which the light modulated by the light modulator is incident; and
a substrate including an upper surface on which the first prism and the plurality of light sources are disposed.

2. The projection device of claim 1, wherein the substrate includes an exposed pad portion, and
the pad portion includes a first pad and a second pad spaced apart from each other.

3. The projection device of claim 2, wherein each of the plurality of light sources is electrically connected to the first pad and the second pad.

4. The projection device of claim 2, comprising a first conductive member and a second conductive member respectively disposed on the first pad and the second pad.

5. The projection device of claim 4, comprising a spacer disposed between the first conductive member and the second conductive member.

6. The projection device of claim 5, wherein each of the light sources is in contact with the spacer.

7. The projection device of claim 4, comprising an adhesive member disposed between the first prism and the upper surface of the substrate.

8. The projection device of claim 7, wherein a height of the adhesive member is different from a height of the first conductive member or the second conductive member.

9. The projection device of claim 7, wherein a height of the adhesive member is greater than a height of the first conductive member or the second conductive member.

10. The projection device of claim 1, wherein the substrate includes an alignment mark formed on the upper surface thereof.

11. The projection device of claim 1,
wherein an upper surface of the first prism is disposed above an upper surface of each of the plurality of light sources.

12. The projection device of claim 1,
wherein the plurality of light sources are disposed at a same height from the upper surface of the substrate.

13. The projection device of claim 1,
wherein in the plurality of light sources, a surface perpendicular to an emission surface of the light faces the upper surface of the substrate.

14. The projection device of claim 1, comprising a collimating member disposed at a front end or a rear end of the first prism.

15. The projection device of claim 14,
wherein the collimating member includes a first collimating member disposed between the first prism and the plurality of light sources.

16. The projection device of claim 15,
wherein the first collimating member is in contact with the first prism.

17. The projection device of claim 15,
wherein the first collimating member is disposed spaced apart from the first prism.

18. The projection device of claim 15,
wherein a first separation distance between the first collimating member and the first prism is smaller than a second separation distance between the first collimating member and the plurality of light sources.

19. The projection device of claim 15,
wherein the first collimating member includes at least one of a Fresnel lens, a total internal reflection (TIR) Fresnel lens, a micro lens array (MLA), or a meta lens.

20. The projection device of claim 14,
wherein the collimating member includes a second collimating member disposed between the first prism and the reflection unit.
